(19) United States
(12) Patent Application Publication
(10) Pub. No.: US 2015/0376778 A1
(43) Pub. Date: Dec. 31, 2015

(54) GRAPHENE GROWTH ON SIDEWALLS OF PATTERNED SUBSTRATE

(71) Applicant: SOLAN, LLC, Salt Lake City, UT (US)

(72) Inventor: Mark Alan Davis, Springville, UT (US)

(21) Appl. No.: 14/765,258

(22) PCT Filed: Feb. 1, 2014
(86) PCT No.: PCT/US14/14342

§ 371 Date: Jul. 31, 2015

Related U.S. Application Data
(60) Provisional application No. 61/759,860, filed on Feb. 1, 2013.

(51) Int. Cl. C23C 16/26; G03F 7/36; H05K 3/40; H01L 21/02; H01L 21/768

(52) U.S. Cl. CPC C23C 16/26; H01L 21/02376; H01L 21/02381; H01L 21/02395; H01L 21/76885; H05K 3/4007; G03F 7/36; H05K 2203/125

(57) ABSTRACT

A method for forming a graphite-based structure comprises patterning a substrate thereby forming a plurality of elements, each respective element in the plurality of elements separated from an adjacent element by a corresponding trench in a plurality of trenches on the substrate. A first element in the plurality of elements has a first surface. A first trench in the plurality of trenches separates the first element from an adjacent element in the plurality of elements, and the first trench has a second surface. The first surface and the second surface are separated by a first side wall of the first element. The method further comprises creating a graphene initiating layer on the first side wall of the first element. The method also comprises generating graphene using the graphene initiating layer thereby forming the graphite-based structure.

### CROSS REFERENCE TO RELATED APPLICATION

The disclosed claims priority to U.S. Patent Application No. 61/759,860, entitled “Segmented Graphene Growth on Side Walls of Elements Formed on a Patterned Substrate Layer,” filed Feb. 1, 2013, which is hereby incorporated by reference herein in its entirety.

### TECHNICAL FIELD

The disclosed embodiments relate generally to methods for growth of graphene layers on patterned substrates and, more particularly, to methods for growth of segmented (e.g., disjoint or isolated) graphene layers on surfaces of a patterned substrate layer.

### BACKGROUND

Graphene-based structures (such as graphene quantum dots, graphene nanoribbons, graphene nanonetworks, graphene plasmonics, and graphene super-lattices) exhibit chemical, mechanical, electronic, and optical properties that have applications and benefits in various electronic devices, composite materials, and implementations for energy generation and storage. Some graphene-based structures require one or more graphene films or one or more graphene layers that are in electrical communication with one another and/or with an external circuit.

Conventional methods to produce such graphene-based structures with one or more graphene layers include forming a continuous graphene film and then patterning (e.g., etching) the continuous graphene film to form isolated graphene layers or films. A disadvantage associated with this approach is that graphene is difficult to process chemically or mechanically. For example, it is difficult to control the etch-rate and etch-selectivity of graphene in relation to other materials used for device fabrication and processing.

Additionally, some methods of segmented graphene growth include oxidation of graphene from specific regions of the continuous graphene sheet to leave isolated graphene substantially in the unoxidized regions. A disadvantage of this oxidative approach to segmented graphene growth includes a loss of active graphene area due to sub-optimal spatial control of the oxidation reaction, thereby compromising the packing density of the segmented graphene layers.

Accordingly, there is a need for fabrication methods and graphene-based structures fabricated using these methods for reliably and controllably forming multiple segmented (e.g., isolated or disjoint) graphene layers.

### SUMMARY

Disclosed are methods for segmented graphene growth that overcome the abovementioned limitations in conventional approaches to obtaining segmented graphene layers. The disclosed embodiments provide methods of fabricating graphene-based structures that are characterized by segmented (e.g., discontinuous or isolated) graphene layers. In some embodiments, the disclosed methods include first patterning a substrate (or a substrate layer) to form device topology that defines the underlying foundation of the graphene-based structure and graphene layers. Subsequently, the disclosed methods include selectively forming graphene-initiating material (such as catalytic metals; carbon compounds such as silicon carbide; or elemental silicon) in regions where isolated graphene-growth is desired. The segmented layers of graphene are then selectively generated using the graphene-initiating materials in regions of the topography where the graphene-initiating materials were selectively formed. The disclosed methods of forming, patterning, and isolating such graphene-initiating materials are better controlled and characterized than the methods of directly patterning graphene. This is because, in the instant methods, there is no absolute requirement that the graphene be patterned. As a result, the resulting fabrication processes allow for improved control in device fabrication, improved spatial resolution, and packing density of the segmented graphene layers.

Accordingly, in some embodiments, a method of forming a graphite-based structure comprises patterning a substrate thereby forming a plurality of elements. Each respective element in the plurality of elements is separated from an adjacent element by a corresponding trench in a plurality of trenches on the substrate. A first element in the plurality of elements has a first surface. A first trench in the plurality of trenches separates the first element from an adjacent element in the plurality of elements, and the first trench has a second surface. The first surface and the second surface are separated by a first side wall of the first element. The first surface is characterized by a first average elevation. The second surface is characterized by a second average elevation. In some embodiments, a first orthogonal projection of the first surface and a second orthogonal projection of the second surface onto a common plane are contiguous or overlapping. The first average elevation is other than the second average elevation. The method further includes creating a graphene initiating layer on the first side wall of the first element. The method also includes generating graphene using the graphene initiating layer thereby forming the graphite-based structure.

### BRIEF DESCRIPTION OF THE DRAWINGS

FIG. 1A illustrates a top view of an exemplary graphene device topography fabricated by exemplary methods in accordance with an embodiment of the present disclosure.

FIG. 1B illustrates a cross-sectional view of the exemplary graphene device topography taken along line 1-1′ of FIG. 1A and fabricated by an exemplary method in accordance with an embodiment of the present disclosure.

FIG. 2A illustrates a top view of an exemplary graphene device topography fabricated by exemplary methods in accordance with an embodiment of the present disclosure.

FIG. 2B illustrates a cross-sectional view of the exemplary graphene device topography taken along line 2-2′ of FIG. 2A and fabricated by an exemplary method in accordance with an embodiment of the present disclosure.

FIG. 2C illustrates a top view of an exemplary graphene device topography fabricated by exemplary methods in accordance with an embodiment of the present disclosure.

FIG. 2D illustrates a cross-sectional view of the exemplary graphene device topography taken along line 2″-2″′ of FIG. 2C and fabricated by an exemplary method in accordance with an embodiment of the present disclosure.

FIG. 2E illustrates a top view of an exemplary graphene device topography fabricated by exemplary methods in accordance with an embodiment of the present disclosure.

FIG. 2F illustrates a cross-sectional view of the exemplary graphene device topography taken along line 2″″-2″″′ of FIG. 2E and fabricated by an exemplary method in accordance with an embodiment of the present disclosure.

FIGS. 3A-3C illustrate top views of exemplary graphene device topographies fabricated by exemplary methods in accordance with embodiments of the present disclosure.

FIGS. 4A-4B are flow diagrams illustrating processes for fabricating graphene device topography by exemplary methods (e.g., using a conformal deposition of a metal based graphene initiating layer; followed by an anisoptropic etch of portions of the metal based graphene initiating layer) in accordance with an embodiment of the present disclosure.

FIGS. 4C-4D are flow diagrams illustrating processes for fabricating graphene device topography by exemplary methods (e.g., including a conformal deposition of a silicon carbide based graphene initiating layer; followed by an anisoptropic etch of portions of the silicon carbide based graphene initiating layer) in accordance with an embodiment of the present disclosure.

FIGS. 4E-4F are flow diagrams illustrating processes for fabricating graphene device topography by exemplary methods (e.g., including a conformal deposition of a silicon based graphene initiating layer; followed by an anisoptropic etch of portions of the silicon based graphene initiating layer) in accordance with an embodiment of the present disclosure.

FIGS. 5A-5D illustrate oblique angle deposition (e.g., using line of sight deposition) and structures formed by oblique angle deposition in accordance with an embodiment of the present disclosure.

FIGS. 6A-6B are flow diagrams illustrating processes for fabricating graphene device topography fabricated by exemplary methods (e.g., including oblique angle deposition of a metal based graphene initiating layer) in accordance with an embodiment of the present disclosure.

FIGS. 6C-6D are flow diagrams illustrating processes for fabricating graphene device topography fabricated by exemplary methods (e.g., including oblique angle deposition of a silicon carbide based graphene initiating layer) in accordance with an embodiment of the present disclosure.

FIGS. 6E-6F are flow diagrams illustrating processes for fabricating graphene device topography fabricated by exemplary methods (e.g., including oblique angle deposition of a silicon based graphene initiating layer) in accordance with an embodiment of the present disclosure.

FIGS. 7A-7B are flow diagrams illustrating processes for fabricating graphene device topography (e.g., with device enhancements, such as plasmonic structures) with segmented graphene films by exemplary methods in accordance with an embodiment of the present disclosure.

FIGS. 8A-8E provides a flowchart illustrating exemplary methods for fabricating graphene device topography in accordance with an embodiment of the present disclosure.

Like reference numerals refer to corresponding parts throughout the drawings.

### DESCRIPTION OF EMBODIMENTS

It will be understood that, although the terms “first,” “second,” etc. are optionally used herein to describe various elements, these elements should not be limited by these terms. These terms are only used to distinguish one element from another. For example, a first element could be termed a second element, and, similarly, a second element could be termed a first element, without changing the meaning of the description, so long as all occurrences of the “first element” are renamed consistently and all occurrences of the second element are renamed consistently. The first element and the second element are both elements, but they are not the same element.

The terminology used herein is for the purpose of describing particular embodiments only and is not intended to be limiting of the claims. As used in the description of the embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

As used herein, the term “sheet” refers to a substantially two-dimensional or one-atom thick substance. For example, a “graphene sheet” refers to one-atom-thick substance with carbon atoms arranged in a hexagonal lattice. A “graphene sheet” also refers to a carbon-based sheet which comprises additional materials such as boron, oxides, dopants and/or edge atomic substitutes.

As used herein, the term “graphene layer” or “graphite layer” refers to one or more graphene sheets (e.g., one, a few, several, several tens, several hundred or several thousands of graphene sheets). The collective thickness of a graphene layer can therefore range between a nanometer to several micrometers, or to several tens of micrometers depending upon the number of graphene sheets in the graphene layer. Final graphene layers produced by the processes disclosed in this application can have a thickness in nanometers, and preferably less than fifty nanometers. The terms “graphene layer” and “graphite layer” are interchangeable in the present disclosure.

As described herein the terms “height” and “elevation” are used. It will be appreciated that these terms are used to note a linear dimension and that, for purposes of illustration in the figures this linear dimension is what is commonly known as the y-direction or height. However, the terms are not so limited. The disclosed devices may be in any orientation. What is of interest is that regardless of their orientation, the disclosed devices include elements having a surface that is spatially separated from neighboring surfaces, that this spatial separation is traversed by a side of such elements, and that graphene may be grown on the side of such elements.

Reference will now be made in detail to various embodiments, examples of which are illustrated in the accompanying drawings. In the following detailed description, numerous specific details are set forth in order to provide a thorough understanding of the invention and the described embodiments. However, the invention may be practiced without these specific details. In other instances, well-known methods, procedures, components, structures and devices have not been described in detail so as not to unnecessarily obscure aspects of the embodiments.

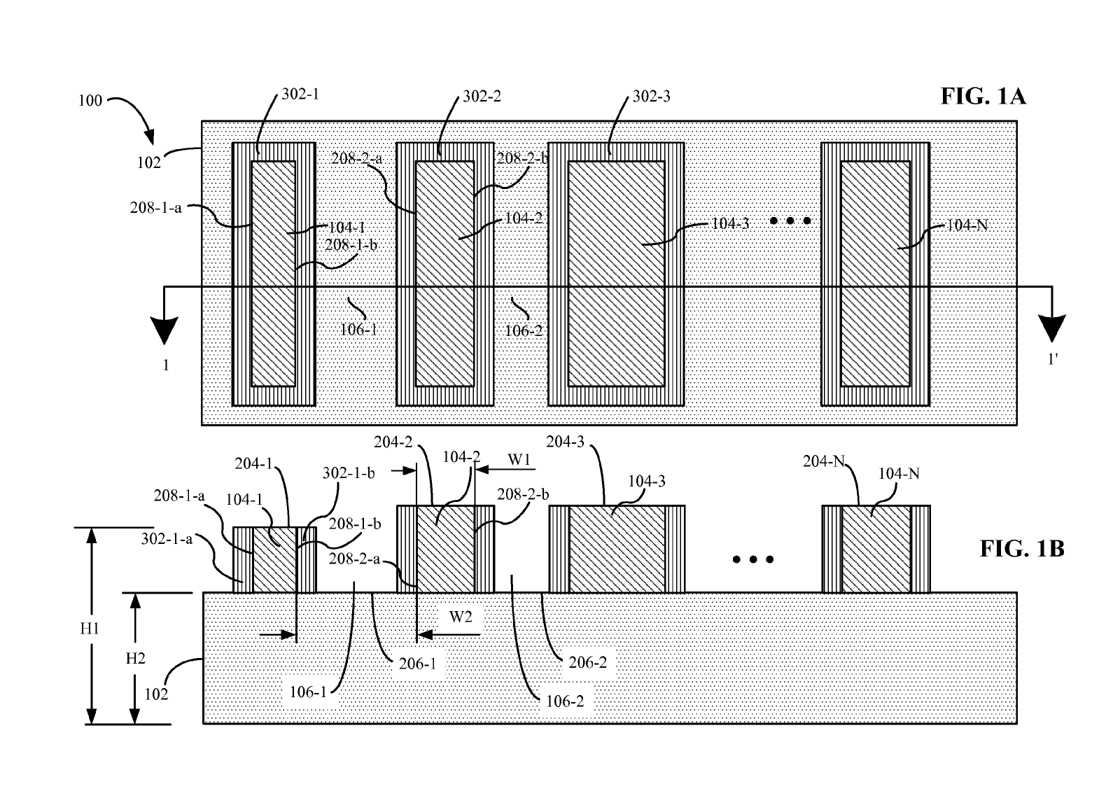

FIG. 1A illustrates a top view of an exemplary graphene device topography 100 fabricated by exemplary methods in accordance with an embodiment of the present disclosure. FIG. 1B illustrates a cross-sectional view of the exemplary graphene device topography 100 taken along line 1-1′ of FIG. 1A. In some embodiments, the graphite-based structure and graphene device topography comprises a structure having at least one graphene layer on at least one surface of the structure. The terms “graphite-based structure” and “graphene device topography” are interchangeable in the present disclosure.

As shown in FIGS. 1A-1B, patterned substrate 102 includes a plurality of elements 104 (e.g., elements 104-1, 104-2, 104-n and the like) on substrate 102. Each respective element in the plurality of elements 104 is separated from an adjacent element by a corresponding trench (e.g., trench 106-1, 106-2, and the like) in a plurality of trenches 106 on the substrate 102.

In some embodiments, a substrate 102 is a solid substance in a form of a thin slice. The substrate can be planar or flexible. In some embodiments, the substrate is made of a dielectric material, a semiconducting material, a metallic material, or a combination of such materials. Exemplary dielectric materials include glass, silicon dioxide, neoceram, and sapphire. Exemplary semiconducting materials include silicon (Si), silicon carbide (SiC), germanium (Ge), boron nitride (BN), and molybdenum sulfide (MoS). Exemplary metallic materials comprise copper (Cu), nickel (Ni), platinum (Pt), gold (Au), cobalt (Co), ruthenium (Ru), palladium (Pd), titanium (Ti), silver (Ag), aluminum (Al), cadmium (Cd), iridium (Ir), combinations thereof, and alloys thereof. In some embodiments the substrate comprises Si, SiO₂, SiC, Cu, Ni, or other materials. In some embodiments, the substrate substantially comprises neoceram, borosilicate glass, germanium arsenide, a IV-V semiconductor material, a substantially metallic material, a high temperature glass, or a combination thereof.

In some embodiments, the substrate 102 substantially comprises SiO₂ glass, soda lime glass, lead glass, doped SiO₂, aluminosilicate glass, borosilicate glass, dichroic glass, germanium/semiconductor glass, glass ceramic, silicate/fused silica, quartz or chalcogenide/sulphide glass. In some embodiments, the substrate is made of poly methyl methacrylate (PMMA), polyethylene terephthalate (PET), polyvinyl alcohol (PVA), or cellulose acetate (CA).

In some embodiments, the substrate 102 includes one layer. In alternative embodiments, the substrate includes a plurality of layers. In some embodiments, a substrate comprises a plurality of overlying layers, each with a different material. In some embodiments, a layer of another substance is applied onto the substrate. In some embodiments, the substrate has crystallographic symmetry. In some embodiments, the substrate is amorphous.

In some embodiments, an element is a feature configured or generated on a substrate. In general, at least a portion of the element is on or above the substrate. In some embodiments, a trench is a recess formed in the substrate such as by etching, a space on or above the substrate formed for example by depositing two adjacent elements on or above the substrate, or a combination thereof.

As shown in FIG. 1B, a first element (e.g., first element 104-1) in the plurality of elements has a first surface (e.g., first surface 204-1, FIG. 1B). A first trench (e.g., first trench 106-1, FIG. 1B) in the plurality of trenches 106 separates the first element from an adjacent element in the plurality of elements, and the first trench has a second surface (e.g., second surface 206-1, FIG. 1B). The first surface (e.g., first surface 204-1, FIG. 1B) and the second surface (e.g., second surface 206-1, FIG. 1B) are separated by a first side wall of the first element (e.g., first side wall 208-1-b of first element 104-1). In some embodiments, the first side wall has a first height (e.g., as shown in FIG. 1B, side wall 208-1 has a first height D1) in a direction substantially perpendicular to a common plane (not shown). In varying embodiments, the first height is between 10 nm and 2 μm, between 15 nm and 1 μm, or between 10 nm and 500 nm. The first surface is characterized by a first average elevation. The second surface is characterized by a second average elevation. The first average elevation is other than the second average elevation. For example, as shown in FIG. 1B, first surface 204-1 of first element 104-1 is characterized by first elevation H1 and second surface 206-1 of trench 106-1 is characterized by second elevation H2, where H1 is distinct from H2.

A first orthogonal projection of the first surface and a second orthogonal projection of the second surface onto a common plane (not shown) are contiguous or overlapping in some embodiments. This means that the first side wall is either perpendicular to the first surface or undercuts the first surface. In some embodiments, the first orthogonal projection of the first surface of the first element on the common plane is characterized by a first dimension (e.g., width) and the second orthogonal projection of the second surface of the first trench on the common plane is characterized by a second dimension (e.g., width). In some embodiments, the first dimension is between 3 nm and 120 nm, between 8 nm and 90 nm, between 3 nm and 40 nm, or between 3 nm and 30 nm. In some embodiments, the second dimension is between 3 nm and 500 nm, between 3 nm and 300 nm, between 10 nm and 100 nm, or between 3 nm and 40 nm.

It will be understood that a fair amount of process variation occurs in the dimensions (e.g., width, height, elevation, etc.) of the features described herein and thus, to a certain extent, dimensions disclosed herein necessarily represent a characteristic or average dimension, taking into account this process variation. Thus, as described herein, numerical values and numerical ranges are given for many characteristic dimensions of the devices and features disclosed herein. It will be appreciated that these dimension are small and therefore, such dimensions may be subject to process variation. For example, the “height” of a side wall may vary. One of skill in the art will appreciate, therefore, that the numerical values and numerical ranges given for many characteristic dimensions of the devices and features disclosed herein are necessarily average values across such devices and features. For instance, in some embodiments such dimensions may vary by five percent or less, ten percent or less, twenty percent or less, thirty percent or less, an order of magnitude or less, or by two or magnitudes or less due to process variations.

In some embodiments, an “orthogonal projection onto a common plane” comprises a projection of an image of a surface onto a plane without enlarging the image. Stated differently, the dimensions of the contours of the surface, when projected onto a common plane exactly match the actual dimensions of the surface that is projected. The construct of “orthogonal projection onto a common plane” has utility when two or more surfaces, which may be spatially separated on a z-axis, are projected along the z-axis onto a common plane. Such a projection is useful for illustrating whether the two projected surfaces are contiguous or overlapping.

FIGS. 1A-1B further illustrate a graphite-based structure 100 formed by generating graphene on each of the side walls 208 of each respective element in the plurality of elements 104. In some embodiments, generating graphene includes generating a respective graphene layer (e.g., graphene layers 302-1, 302-2, 302-3, and the like) on each of the side walls of each respective element of the plurality of elements 104. In some embodiments, generating graphene includes generating a respective graphene layer (e.g., graphene layers 302-1, 302-2, 302-3, and the like) on the first side wall 208-1-a of the first element 104-1 of the plurality of elements 104. As shown in FIGS. 1A-1B, the generated graphene layers 302 (e.g., including graphene layer 302-1 on the side walls 208-1 of element 104-1, graphene layer 302-2 on the side walls 208-2 of element 104-2, and the like) are segmented (e.g., mutually disjoint, discontinuous, non-overlapping and/or isolated from one another).

In some embodiments, the respective graphene layer comprises about 1 to 300 graphene sheets. In some embodiments, the graphene layer comprises 1 graphene sheet. In various embodiments, the graphene layer comprises between 2 and 10 graphene sheets, between 10 and 30 graphene sheets, between 25 and 50 graphene sheets, between 50 and 100 graphene sheets, or over 100 graphene sheets. In some embodiments, the graphene layer has a thickness that is between 1 to 100 nm. In some embodiments, a sheet is a substantially two-dimensional or one-atom thick substance. In some embodiments, a graphene sheet is a one-atom-thick substance with carbon atoms arranged in a hexagonal lattice. In some embodiments, a graphene sheet is a carbon-based sheet which comprises additional materials such as boron, oxides, dopants and/or edge atomic substitutes. In some embodiments, a graphene sheet is a carbon-based sheet doped with boron or other elements.

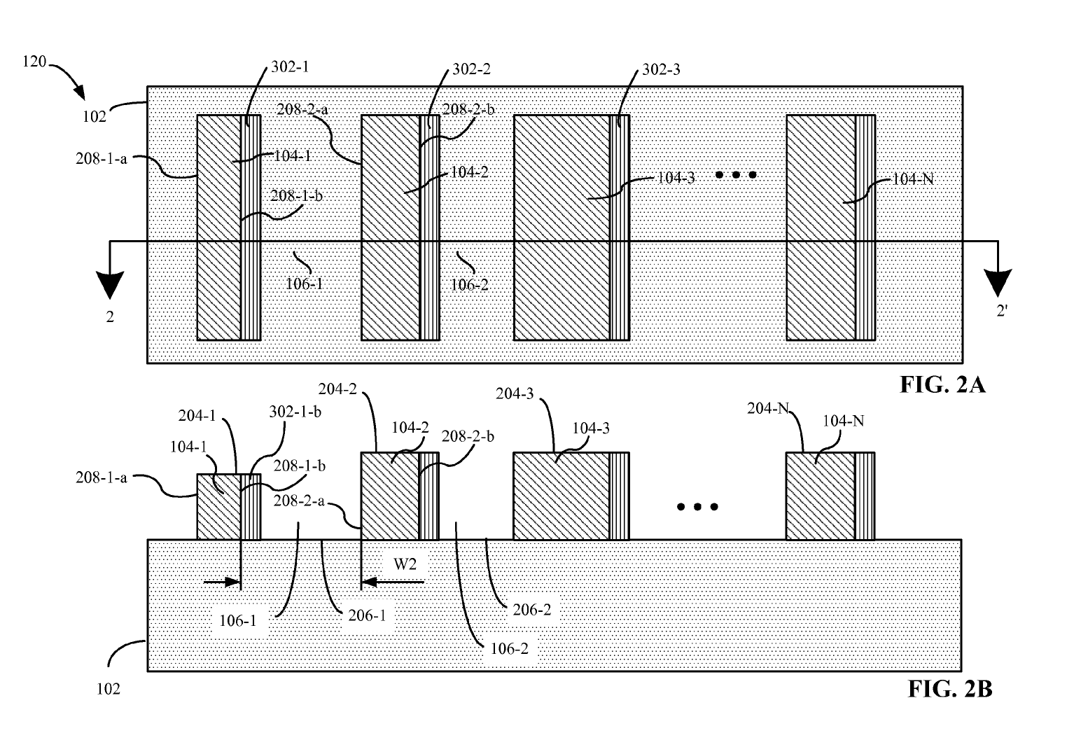

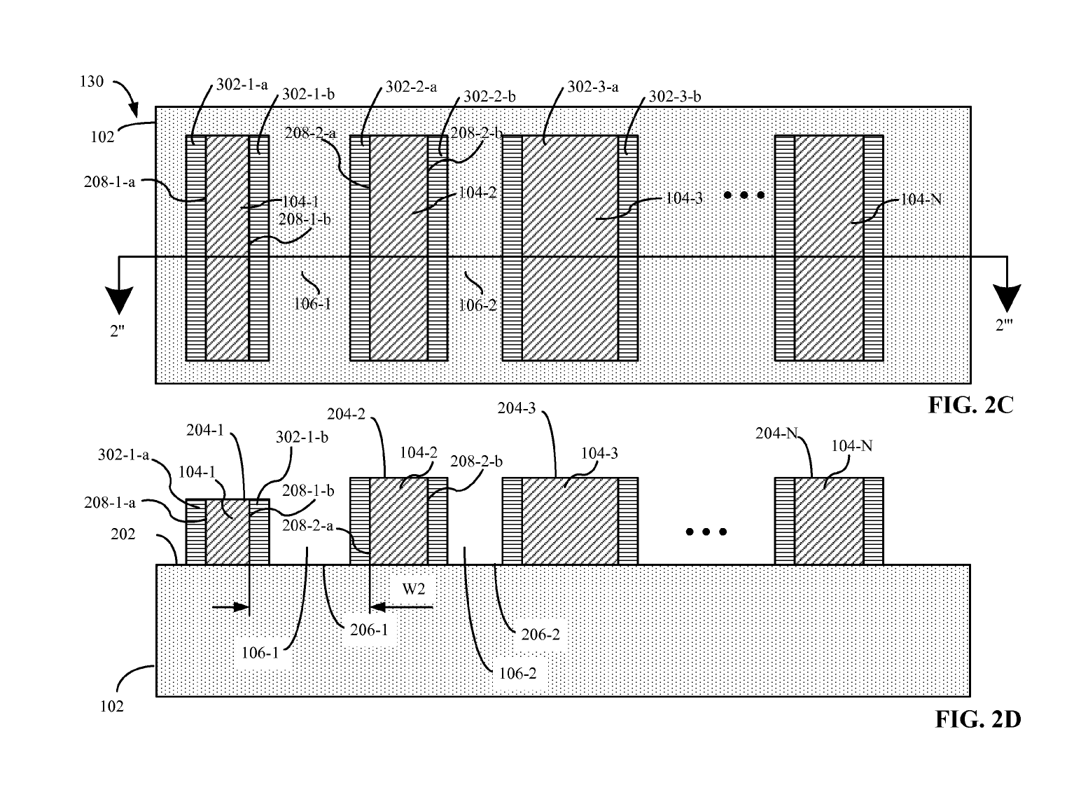

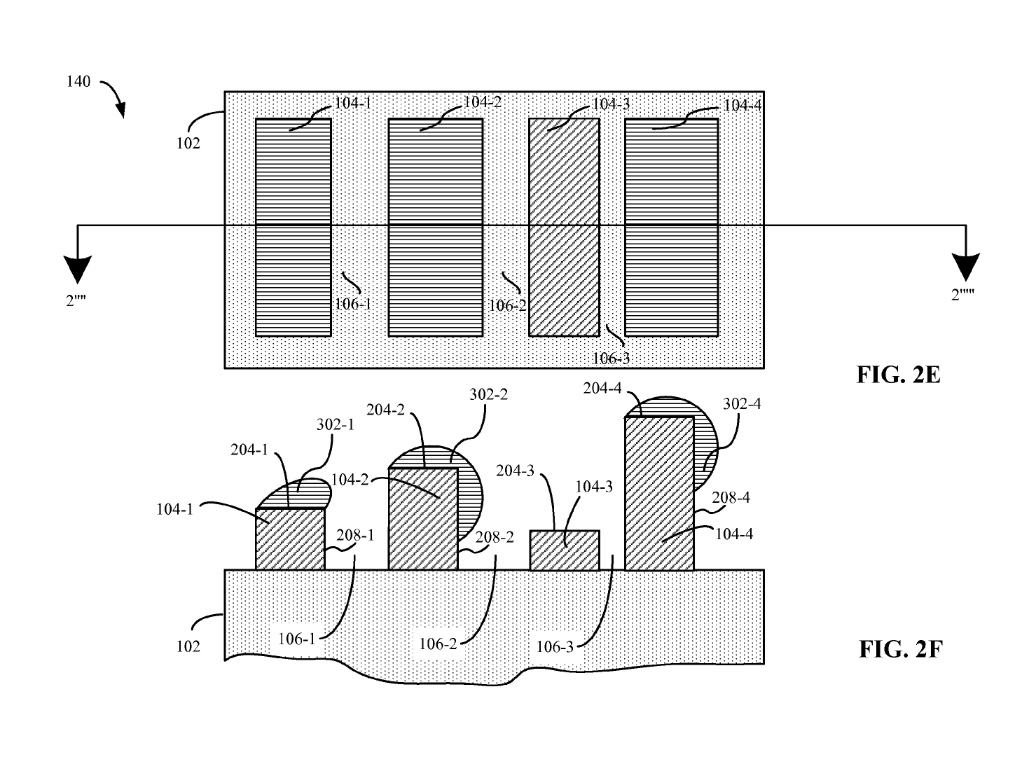

FIG. 2A shows a top view of an exemplary graphene device topography 120 fabricated by exemplary methods in accordance with an embodiment of the present disclosure. FIG. 2B illustrates a cross-sectional view of the exemplary graphene device topography 120 taken along line 2-2′ of FIG. 2A and fabricated by an exemplary method in accordance with an embodiment of the present disclosure.

FIGS. 2A-2B further illustrate a graphite-based structure 120 formed by generating graphene on a side wall 208 of each respective element (e.g., on corresponding side walls, lying in parallel planes, of the respective elements) in the plurality of elements 104. In some embodiments, generating graphene includes generating a respective graphene layer (e.g., graphene layers 302-1, 302-2, 302-3, and the like) on the side wall (e.g., lying along parallel planes; e.g., side wall 208-1-b of element 104-1, side wall 208-2-b of element 104-2, and the like that lie in parallel planes) of each respective element of the plurality of elements 104. As shown in FIGS. 2A-2B, the generated graphene layers 302 (e.g., including graphene layer 302-1 on the side wall 208-1-b of element 104-1, graphene layer 302-2 on the side wall 208-2-b of element 104-2, and the like) are segmented (e.g., mutually disjoint, discontinuous, non-overlapping or isolated from one another).

FIG. 2C shows a top view of an exemplary graphene device topography 130 fabricated by exemplary methods in accordance with an embodiment of the present disclosure. FIG. 2D illustrates a cross-sectional view of the exemplary graphene device topography 130 taken along line 2″-2″′ of FIG. 2C and fabricated by an exemplary method in accordance with an embodiment of the present disclosure.

FIGS. 2C-2D further illustrate a graphite-based structure 130 formed by generating graphene on a pair of side walls 208 (e.g., a pair of side walls lying in parallel planes) of each respective element in the plurality of elements 104. In some embodiments, generating graphene includes generating a respective graphene layer (e.g., graphene layers 302-1-a and 302-1-b, 302-2-a and 302-2-b, 302-3-a and 302-3-b, and the like) on each side wall of the pair of side walls (e.g., a pair of side walls lying along parallel planes; e.g., side walls 208-1-a and 208-1-b of element 104-1, side walls 208-2-a and 208-2-b of element 104-2, and the like) of each respective element of the plurality of elements 104. As shown in FIGS. 2C-2D, the generated graphene layers 302 (e.g., including graphene layer 302-1-a and 302-1-b respectively on the side walls 208-1-a and 208-1-b of element 104-1, graphene layers 302-2-a and 302-2-b respectively on the side walls 208-2-a and 208-2-b of element 104-2, and the like) are segmented (e.g., mutually disjoint, discontinuous, non-overlapping or isolated from one another).

FIG. 2E shows a top view of an exemplary graphene device topography 140 fabricated by exemplary methods in accordance with an embodiment of the present disclosure. FIG. 2F illustrates a cross-sectional view of the exemplary graphene device topography 140 taken along line 2″″-2″″′ of FIG. 2E and fabricated by an exemplary method in accordance with an embodiment of the present disclosure.

FIGS. 2E-2F illustrate a graphite-based structure 140 formed by generating graphene on side walls 208 (e.g., on corresponding side walls, lying in parallel planes, of the respective elements) and/or on the top surfaces 204 of one or more respective elements in the plurality of elements 104. In some embodiments, generating graphene includes generating a respective graphene layer (e.g., graphene layers 302-1, 302-2, 302-4, and the like) on a side wall of the pair of side walls and/or on the top surface of one or more respective elements of the plurality of elements 104. As shown in FIGS. 2E-2F, the generated graphene layers 302 (e.g., including graphene layer 302-1 on the top surface 204-1 of element 104-1, graphene layer 302-2 on the top surface 204-2 and side wall 208-2 of element 104-2, graphene layer 302-4 on the top surface 204-4 and side wall 208-4 of element 104-4 and the like) are segmented (e.g., mutually disjoint, discontinuous, non-overlapping or isolated from one another).

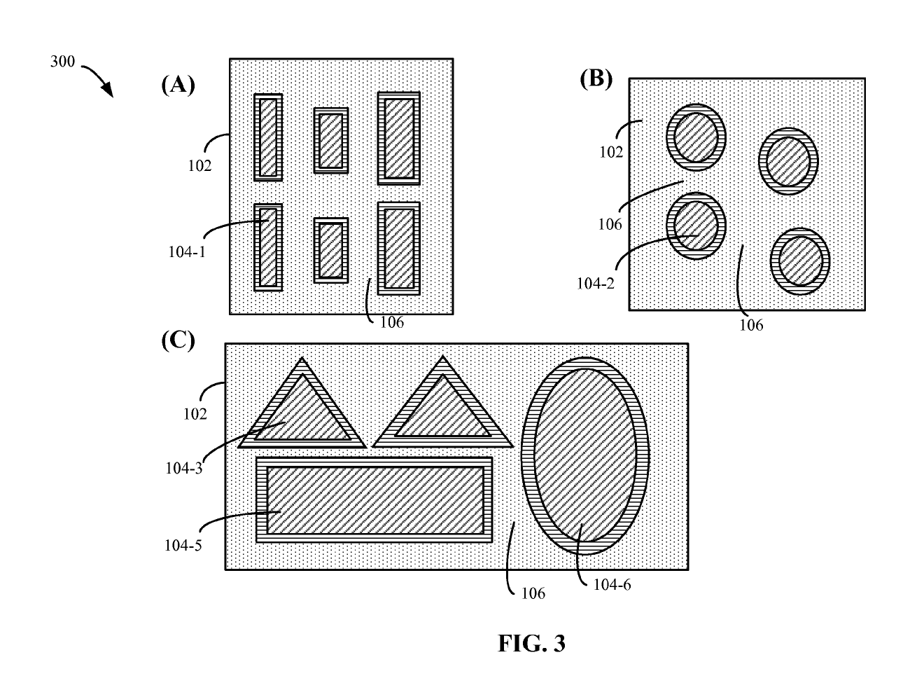

FIGS. 3A-3C illustrate top views of exemplary graphene device topographies fabricated by exemplary methods in accordance with embodiments of the present disclosure. The graphene device topographies shown in FIGS. 3A-3C include graphene layers on each respective side wall of each of the device structures.

Continuing to refer to FIGS. 3A-3C, in some embodiments, the first element in the plurality of elements 104 is a rib. In some embodiments, the rib has a length and a width, where the length is at least two times the width. In some embodiments, the rib has a length and a width, where the length is between two times and five times the width. For example, the elements 104 (e.g., element 104-1) shown in FIG. 3A are ribs having a length and a width, where the length is at least two times the width.

In various embodiments, a width of a rib is between 1 nm and 10 nm, between 10 nm and 20 nm, between 20 nm and 30 nm, between 30 nm and 40 nm, between 50 nm and 100 nm, or between 100 nm and 500 nm. In some embodiments, each rib in a plurality of ribs has a width that is on the order of nanometers in width and this width does not deviate from the width of any other rib in the plurality of ribs by more than 0.1 nm, by more than 0.2 nm, by more than 0.3 nm, by more than 0.4 nm, by more than 0.5 nm, by more than 0.6 nm, by more than 0.7 nm, by more than 0.8 nm, by more than 0.9 nm, by more than 1 nm, by more than 2 nm, by more than 3 nm, by more than 4 nm, or by more than 5 nm.

In some embodiments, a first element in the plurality of elements 104 is a mesa. In some embodiments, a mesa is an island isolated from other features on the substrate or a plateau on the substrate. In some embodiments, a mesa has at least one dimension (e.g., width or length) that is relatively large and thus can be used as a basis for further processing of more complex structures. In some embodiments, a mesa has a topographical height feature, providing a capability for vertical isolation and/or size for desired functionality. In some embodiments, the at least one dimension of the mesa is between 10 nm and 100 nm, between 100 nm and 1 μm, or between 1 μm and 10 μm. In some embodiments, the largest dimension of the mesa (e.g., width or length) is on the order of nanometers and does not deviate from the largest dimension of any other mesa in a plurality of mesas by more than 0.1 nm, by more than 0.2 nm, by more than 0.3 nm, by more than 0.4 nm, by more than 0.5 nm, by more than 0.6 nm, by more than 0.7 nm, by more than 0.8 nm, by more than 0.9 nm, by more than 1 nm, by more than 2 nm, by more than 3 nm, by more than 4 nm, or by more than 5 nm.

In some embodiments, the first element in the plurality of elements 104 is a pillar. In some embodiments, the top surface of the pillar (e.g., pillar 104-2, FIG. 3B) is substantially circular. In some embodiments, the top surface of the pillar (e.g., pillar 104-6, FIG. 3C) is substantially ovoid. In some embodiments, the top surface of the pillar (e.g., pillar 104-3, FIG. 3C) on is substantially polygonal. In some embodiments, the top surface of the pillar has an arcuate edge. In some embodiments, the elements 104 have holes within them.

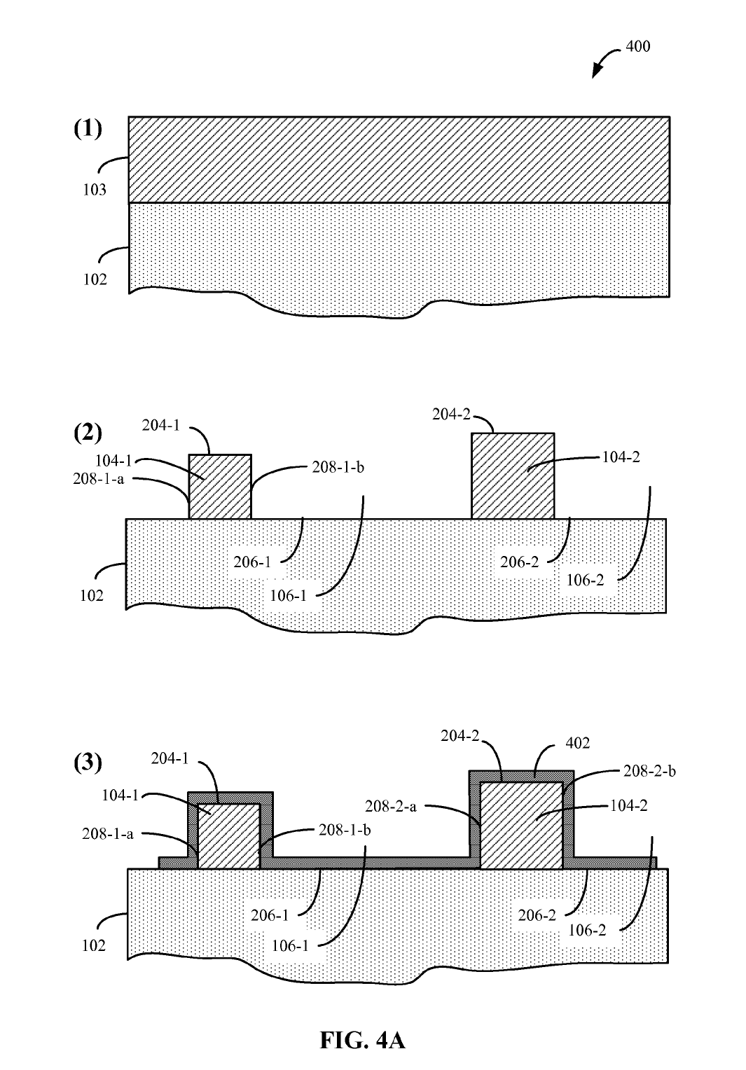

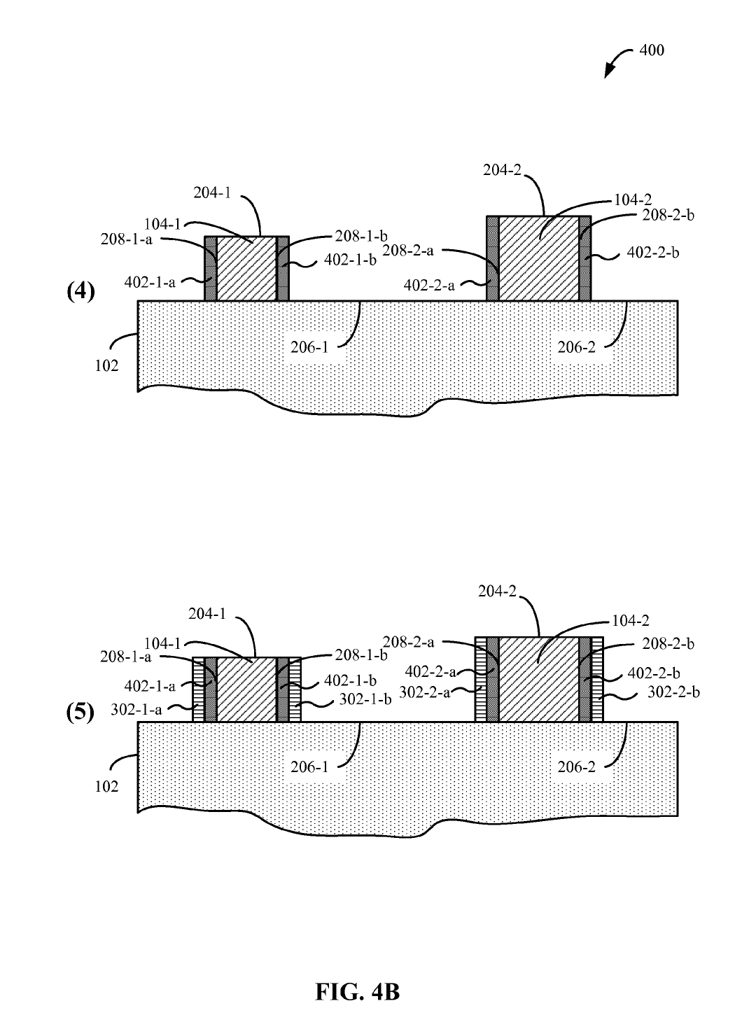

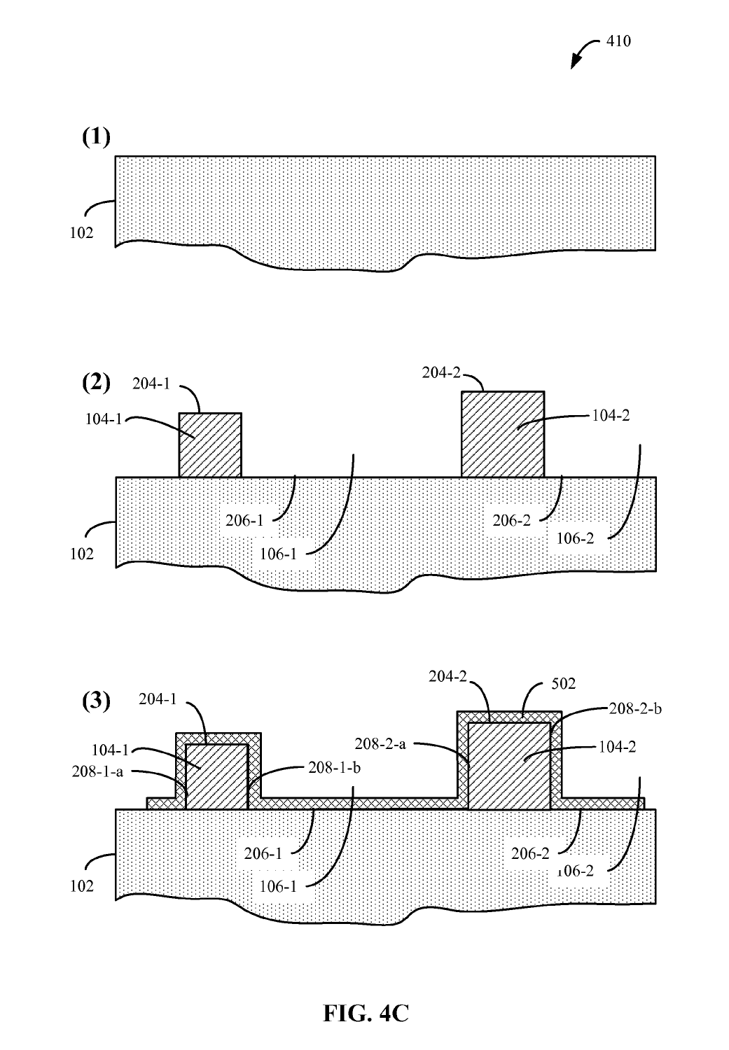

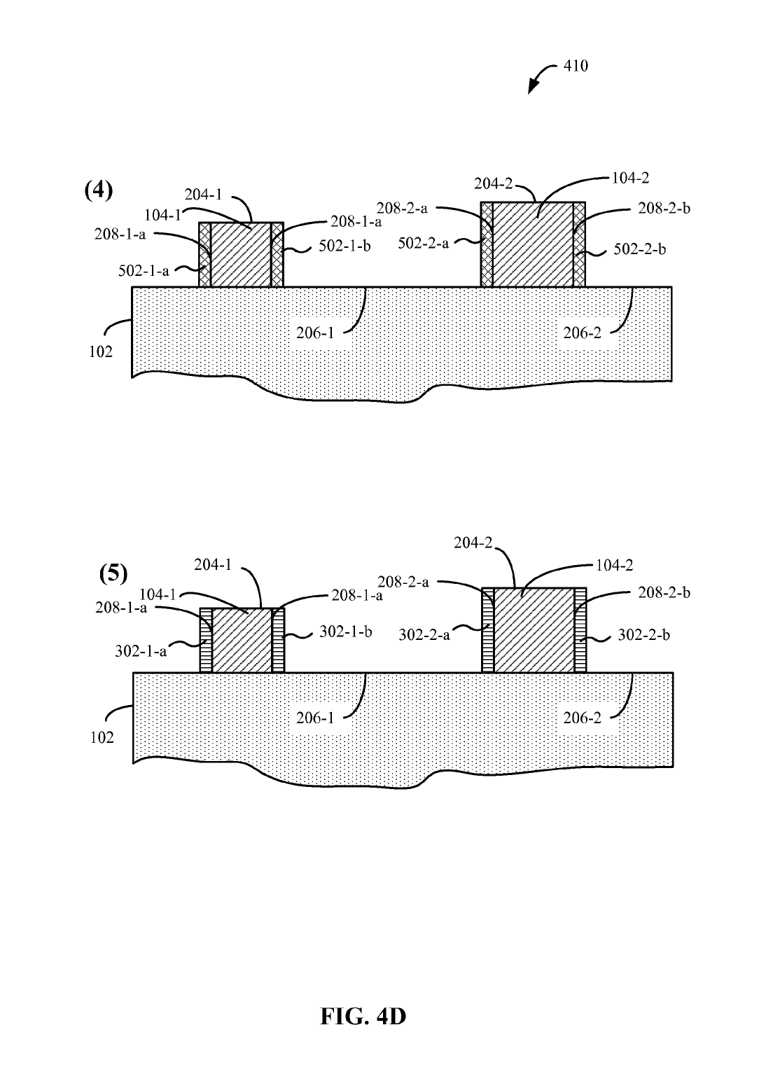

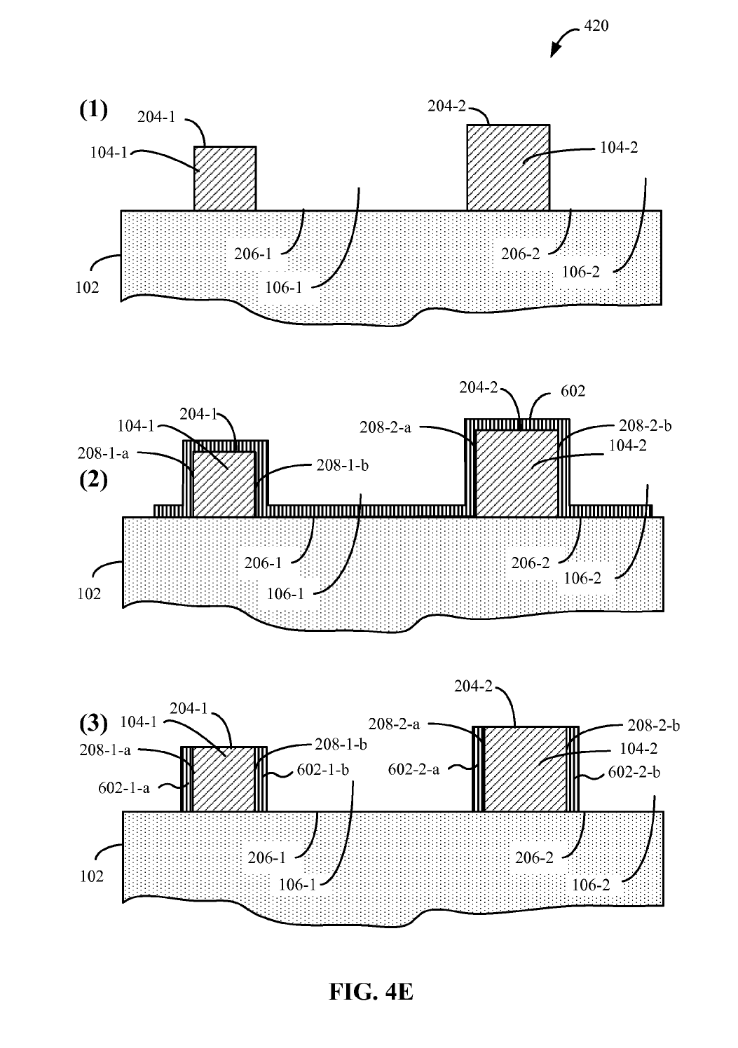

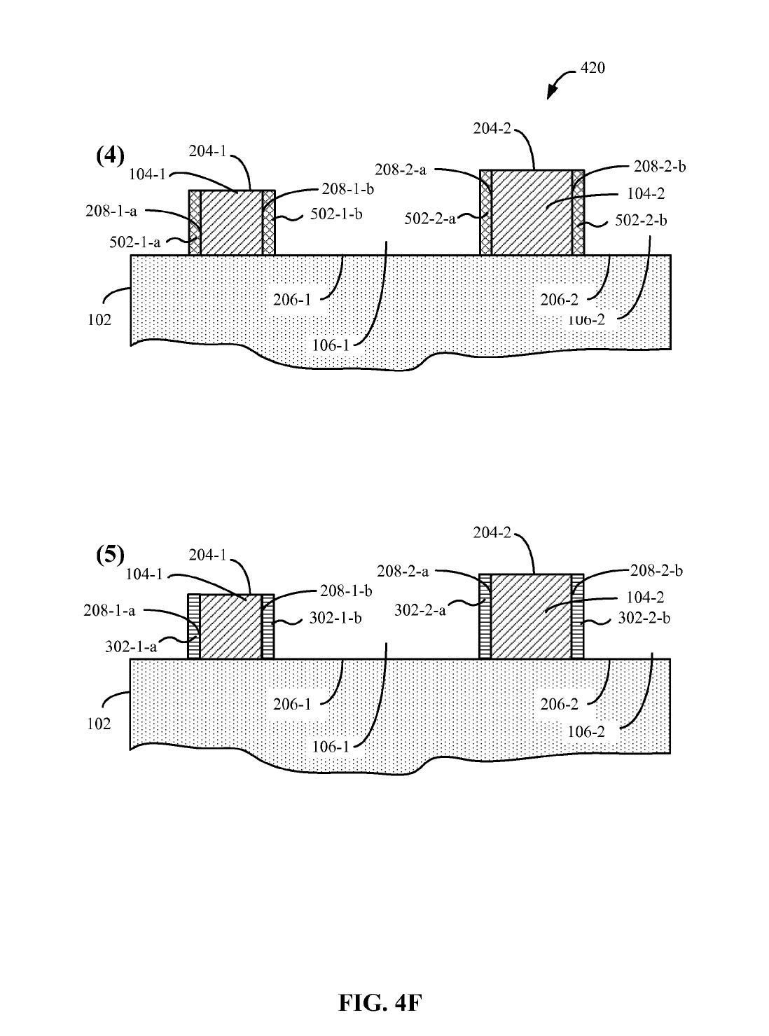

FIGS. 4A-4B include flow diagrams illustrating process 400 for fabricating a graphene device in accordance with exemplary methods (e.g., using a conformal deposition of a metal based graphene initiating layer; followed by an anisoptropic etch of portions of the metal based graphene initiating layer) in accordance with an embodiment of the present disclosure. It will be understood that, in some embodiments, the illustrative devices shown in FIGS. 4A-4F are cross-sectional views of the device topography. In such embodiments, the graphene device topography formed by the exemplary methods described in FIGS. 4A-4F have a top view as illustrated in FIG. 1A (e.g., with graphene growth on all side walls of each respective element of the plurality of elements 104).

In some embodiments, as shown in step 400-1 of FIG. 4A, in some embodiments, a substrate comprises a plurality of layers that overlay each other. As illustrated in FIG. 4A, in some embodiments, the substrate comprises a plurality of materials, including a first material of a first substrate layer 103 and a second material of the base substrate.

As shown in step 400-2 of FIG. 4A, the substrate (e.g., comprising substrate layer 103) is patterned to form a plurality of elements 104 (e.g., elements 104-1 and 104-2). In this way, each element in the plurality of elements 104 is separated from an adjacent element on the substrate by a corresponding trench (e.g., trench 106-1, 106-2, and the like) in a plurality of trenches 106 on the substrate. In some embodiments, the plurality of trenches 106 is formed by removing predetermined regions of substrate layer 103. In some embodiments, the predetermined regions of substrate layer 103 are removed by etching the plurality of trenches into the substrate layer 103. In some embodiments, the substrate layer 103 comprises a photoresist material and portions of the layer (e.g., here, photoresist material) are removed from the predetermined regions of the substrate layer 103 using photolithography.

In alternative embodiments, the substrate comprises a single layer (e.g., made of a substrate material). In such embodiments, the plurality of trenches is formed by removing portions of substrate material from predetermined regions of the substrate. In some embodiments, portions of the substrate material are removed by etching the plurality of trenches into the substrate. In some embodiments, the plurality of trenches are etched into the substrate or into respective substrate layer 103 by photolithography, X-ray lithography, reactive ion-etching, plasma etching, sputter etching, e-beam direct writing, or a combination thereof. In some embodiments, the plurality of elements is formed by selectively patterning or growing a Block co-polymer (e.g., blocks of two or more monomers, such as polystyrene and poly(methyl methacrylate) (PMMA), covalently bonded together) on portions of substrate 102 at regions of the substrate corresponding to the plurality of elements 104. In some embodiments, the block copolymer is patterned using methods such as photolithography or dry etching to define the plurality of elements on the substrate.

Further, as shown in step 400-3 of FIG. 4A, a graphene initiating layer (e.g., metal based graphene initiating layer 402) is conformally deposited (e.g., deposited uniformly, such as with uniform, consistent or regular thickness) onto substantially all of the exposed surfaces (e.g., including onto top surfaces 204 and side walls 208 of each element in the plurality of elements 104 and onto trench surfaces 206 of trenches 106) of the patterned substrate (e.g., on the topography formed in step 400-2 of FIG. 4A). In some embodiments, the graphene initiating layer substantially comprises a metal selected from the group consisting of: platinum, gold, palladium, ruthenium, aluminum, titanium, tungsten, cadmium, copper, nickel, nickel foam, iron, or combinations thereof. In some embodiments, the metal graphene initiating layer is conformally deposited through atomic layer deposition (ALD) onto the first surface 204-1 and the first side wall 208-1-b of the first element 104-1 and onto the second surface 206-1 of the first trench 106-1. In some embodiments, the metal graphene initiating layer is conformally deposited through chemical vapor deposition (CVD) onto the first surface 204-1 and the first side wall 208-1-b of the first element 104-1 and onto the second surface 206-1 of the first trench 106-1.

As shown in step 400-4 of FIG. 4B, after conformally depositing graphene initiating layer (e.g., metal based graphene initiating layer 402), portions of the graphene initiating layer (e.g., the graphene initiating layer on the top surface of each element, such as graphene initiating layer on first surface 204-1 of element 104-1; and the graphene initiating layer on the trench surface of each trench, such as graphene initiating layer on second surface 206-1 of trench 106-1) is directionally etched (e.g., anisotropically etched, or etched preferentially in one or more directions or axes of etching compared to at least another direction or axis; in other words, a preferential etch-rate in one or more directions or axes of etching is substantially greater than an etch rate in at least another direction or axis) to retain graphene initiating layer on the side walls of the respective elements (e.g., on first side wall 208-1-b of element 104-1, side wall 208-2-b of element 104-2, and the like).

Further, as shown in step 400-5 of FIG. 4B, a graphite-based structure is formed by generating graphene using the graphene initiating layer (e.g., generating graphene layers 302-1-a and 302-1-b, 302-2-a and 302-2-b using segmented metal graphene initiating layers 402-1-a and 402-1-b, 402-2-a and 402-2-b, respectively). In some embodiments, graphene is generated using the graphene initiating layer 402 by growing a carbon material on the graphene initiating layer thereby forming the graphite-based structure. In some embodiments, the carbon material is deposited on the graphene initiating layer and the deposited carbon material is heated thereby forming the graphite-based structure.

FIGS. 4C-4D include flow diagrams illustrating process 410 for fabricating graphene devices by exemplary methods (e.g., including a conformal deposition of a silicon carbide based graphene initiating layer; followed by an anisoptropic etch of portions of the silicon carbide based graphene initiating layer) in accordance with an embodiment of the present disclosure.

Shown in step 410-1 of FIG. 4C, is a substrate 102 comprising a substrate material. In some embodiments, the substrate substantially comprises neoceram, barosilicate glass, germanium arsenide, a IV-V semiconductor material, a substantially metallic material, a high temperature glass, or a combination thereof. In some embodiments, the substrate substantially comprises SiO₂ glass, soda lime glass, lead glass, doped SiO₂, aluminosilicate glass, borosilicate glass, dichroic glass, germanium/semiconductor glass, glass ceramic, silicate/fused silica, quartz or chalcogenide/sulphide glass. In some embodiments, the substrate substantially comprises any of the materials disclosed for substrates herein.

As shown in step 410-2 of FIG. 4C, in some embodiments, substrate 102 is patterned to form a plurality of elements 104 (e.g., elements 104-1 and 104-2), each of which is separated from an adjacent element on the substrate 102 by a corresponding trench (e.g., trench 106-1, 106-2, and the like) in a plurality of trenches 106 on substrate 102. In some embodiments, the plurality of elements 104 is formed by growing portions of substrate material selectively at regions of the substrate corresponding to the plurality of elements. Alternatively, or in addition, as shown in step 400-2, the plurality of elements is formed by growing at least one respective secondary material, distinct from a substrate material, selectively on regions of the substrate corresponding to the plurality of elements.

In other words, in some embodiments, the plurality of elements 104 comprises substantially the same material as substrate 102. In alternative embodiments, the plurality of elements 104 comprises a respective secondary material, distinct from the substrate material. In some embodiments, the respective secondary material comprises one or more of: a dielectric material, a metal oxide, a metal nitride, a semi-conductor material, a metal, or a combination thereof.

Further, as shown in step 410-3 of FIG. 4C, a graphene initiating layer (e.g., silicon carbide based graphene initiating layer 502) is conformally deposited (e.g., using atomic layer deposition or chemical vapor deposition) onto all of the exposed surfaces (e.g., including onto top surfaces 204 and side walls 208 of each element in the plurality of elements 104 and onto trench surfaces 206 of trenches 106) of the patterned substrate (e.g., on the topography formed in step 400-2). In some embodiments, the silicon carbide graphene initiating layer is conformally deposited through atomic layer deposition (ALD) or chemical vapor deposition (CVD) onto the first surface 204-1 and the first side wall 208-1-b of the first element 104-1 and onto the second surface 206-1 of the first trench 106-1.

As shown in step 410-4 of FIG. 4D, after conformally depositing graphene initiating layer (e.g., silicon carbide based graphene initiating layer 502), portions of the graphene initiating layer (e.g., the graphene initiating layer on the top surface of each element, such as graphene initiating layer on first surface 204-1 of element 104-1; and the graphene initiating layer on the trench surface of each trench, such as graphene initiating layer on second surface 206-1 of trench 106-1) are directionally etched (e.g., anisotropically etched, or etched preferentially in one or more directions or axes of etching compared to at least another direction or axis) to retain graphene initiating layer on the side walls of the respective elements (e.g., on first side wall 208-1-b of element 104-1, side wall 208-2-b of element 104-2, and the like).

Further, as shown in step 400-5 of FIG. 4D, a graphite-based structure is formed by generating graphene using the graphene initiating layer (e.g., generating graphene layers 302-1-a and 302-1-b, 302-2-a and 302-2-b using segmented silicon carbide based graphene initiating layers 502-1-a and 502-1-b, 502-2-a and 502-2-b, respectively). In some embodiments, when graphene initiating layer 502 is made of silicon carbide, graphene layers 302 are generated using graphene initiating layers 502 by heating the silicon carbide to vaporize elemental silicon in the silicon carbide, thereby forming graphite-based structure. More generally, in some embodiments, where the graphene initiating layer substantially comprises a compound of carbon (e.g., silicon carbide), graphene is generated by heating the graphene initiating layer to vaporize an element other than carbon from the compound of carbon, thereby forming the graphite-based structure.

FIGS. 4E-4F include flow diagrams illustrating process 420 for fabricating graphene devices by the disclosed exemplary methods (e.g., including a conformal deposition of a silicon based graphene initiating layer; followed by an anisoptropic etch of portions of the silicon based graphene initiating layer) in accordance with an embodiment of the present disclosure.

Shown in step 420-1 of FIG. 4E is a patterned substrate (e.g., fabricated by one or more of the process steps 400-1 and 400-2 described with reference to FIG. 4A; and process steps 410-1 and 410-2 described with reference to FIG. 4C). As shown in step 420-2 of FIG. 4E, a graphene initiating layer (e.g., silicon based graphene initiating layer 602) is conformally deposited (e.g., using atomic layer deposition or chemical vapor deposition) onto all of the exposed surfaces (e.g., including onto top surfaces 204 and side walls 208 of each element in the plurality of elements 104; and onto trench surfaces 206 of the plurality of trenches 106) of the patterned substrate (e.g., on the topography formed in step 420-2). In some embodiments, the silicon graphene initiating layer is conformally deposited through atomic layer deposition (ALD) or chemical vapor deposition (CVD) onto the first surface 204-1 and the first side wall 208-1-b of the first element 104-1 and onto the second surface 206-1 of the first trench 106-1.

As shown in step 420-3 of FIG. 4E, after conformally depositing graphene initiating layer (e.g., silicon based graphene initiating layer 602), portions of the graphene initiating layer (e.g., the graphene initiating layer on the top surface of each element, such as graphene initiating layer on first surface 204-1 of element 104-1; and the graphene initiating layer on the trench surface of each trench, such as graphene initiating layer on second surface 206-1 of trench 106-1) are directionally etched (e.g., anisotropically etched, or etched preferentially in one or more directions or axes of etching compared to at least another direction or axis) to retain graphene initiating layer on the side walls of the respective elements (e.g., on side walls 208-1-a and 208-1-b of element 104-1, side walls 208-2-a and 208-2-b of element 104-2, and the like).

Further, as shown in steps 420-4 and 420-5 of FIG. 4F, a graphite-based structure is formed by generating graphene using the graphene initiating layer 602 (e.g., including segmented silicon graphene initiating layers 602-1-a and 602-1-b on the side walls of first element 104-1 and silicon graphene initiating layers 602-2-a and 602-2-b on the side walls of second element 104-2). As shown in step 600-4, in some embodiments, graphene is generated using the graphene initiating layer by depositing elemental carbon on or into the silicon graphene initiating layer and by subsequently converting the silicon graphene initiating layer into silicon carbide (e.g., silicon carbide layer 502, including silicon carbide layers 502-1-a and 502-1-b on the side walls of first element 104-1 and silicon carbide layers 502-2-a and 502-2-b on the side walls of second element 104-2) by enabling a chemical reaction of the silicon graphene initiating layer with the deposited elemental carbon. In some embodiments, elemental carbon is deposited on or into the silicon graphene initiating layer 602 by doping the silicon graphene initiating layer 602 through implantation of the elemental carbon into the silicon graphene initiating layer 602. Further, as shown in step 420-5, the silicon carbide is heated to vaporize the silicon from the silicon carbide by reverse epitaxy, thereby forming the graphite-based structure (e.g., including segmented graphene layers 302-1-a and 302-1-b on the side walls of first element 104-1 and segmented graphene layers 302-2-a and 302-2-b on the side walls of second element 104-2).

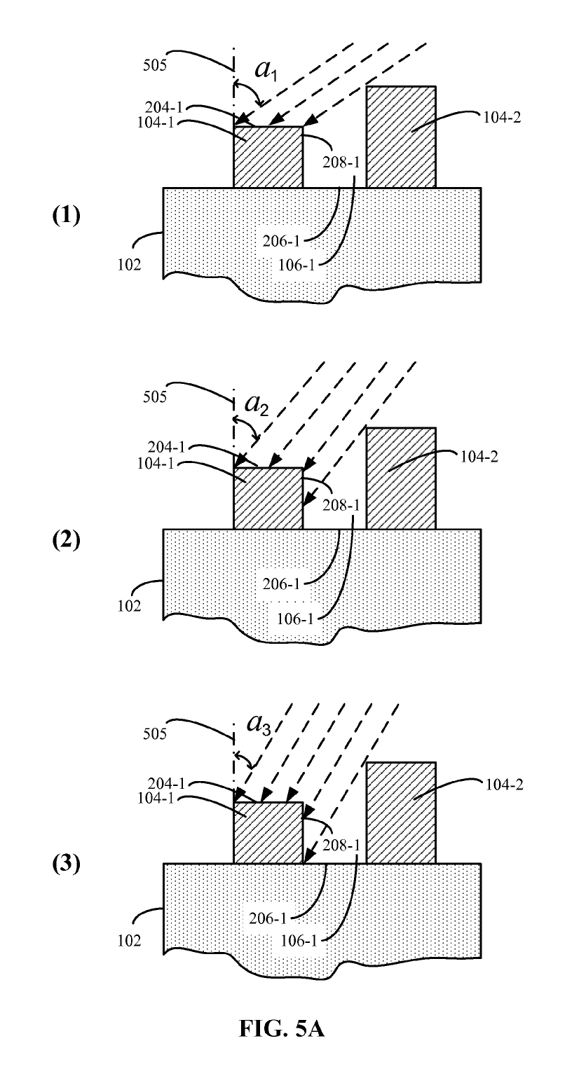

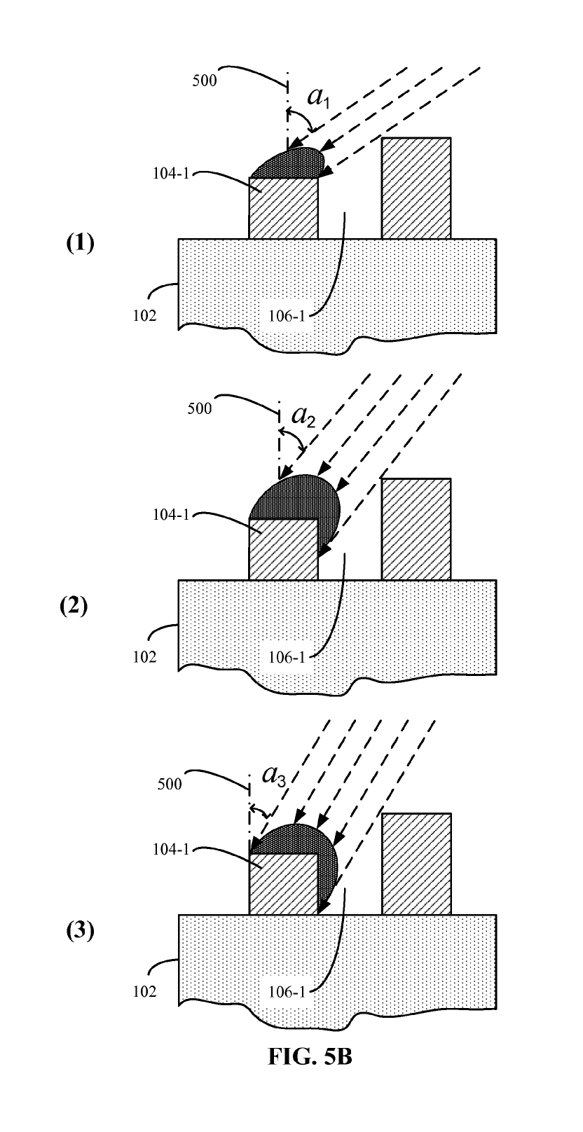

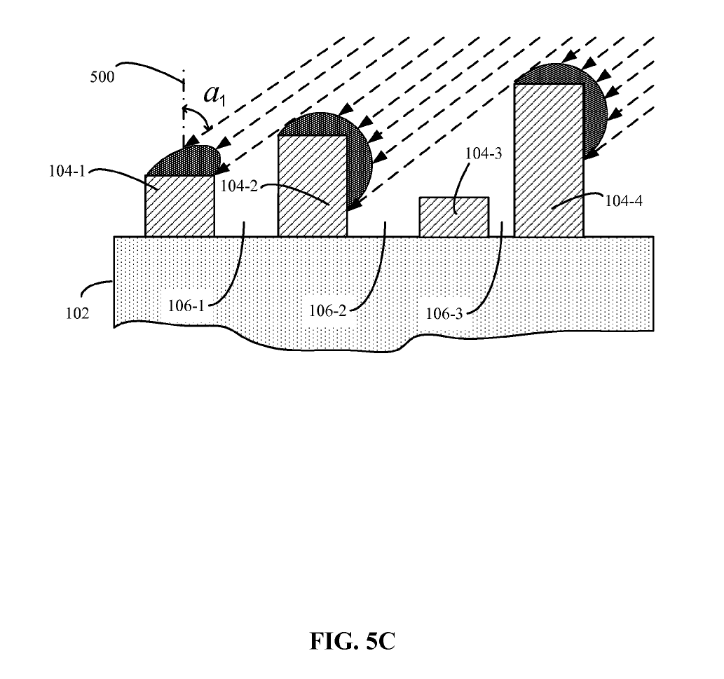

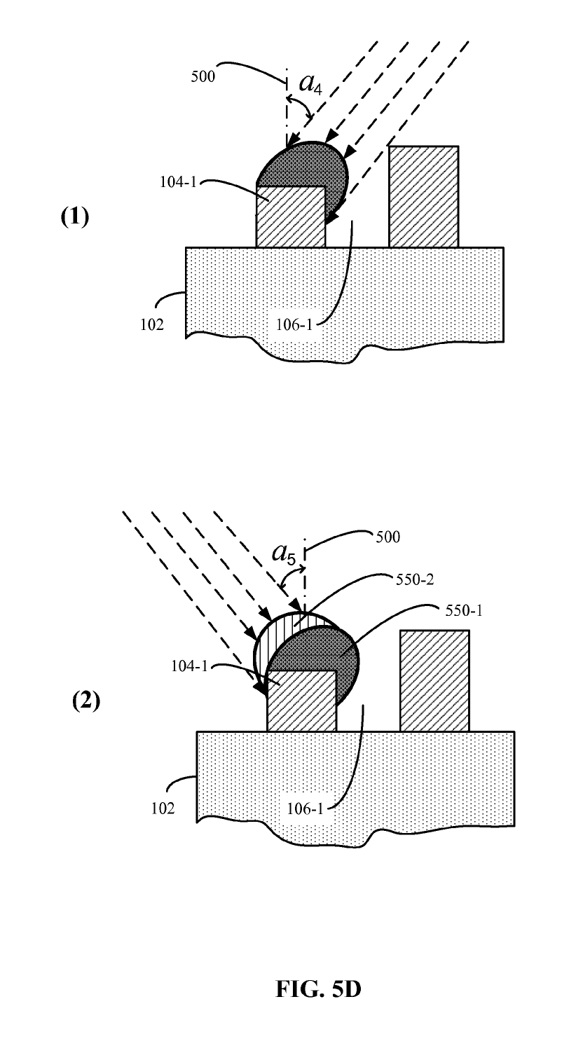

FIGS. 5A-5D illustrate oblique angle deposition (e.g., using line of sight deposition) and structures formed by oblique angle deposition, in accordance with an embodiment of the present disclosure. In some embodiments, a predetermined angle of incidence of the deposition material is an angle made by a direction of flow of the deposition material with respect to a central axis of one or more of the plurality of elements formed on the patterned substrate (e.g., predetermined angle of incidence α₁, FIG. 5A-1; predetermined angle of incidence α₂ FIG. 5A-2; predetermined angle of incidence α₃, FIG. 5A-3; and the like).

FIGS. 5A-5B illustrate the effect of the predetermined angle of incidence of a deposition material on the material deposition profile (e.g., due to line of sight effect), for a given fixed substrate geometry (e.g., for a given device pattern or topography, such as for a given set of dimensions of elements and/or trenches formed on the substrate and/or for a given spacing between adjacent elements formed on the substrate). Accordingly, shown in FIG. 5A-1 is a first predetermined angle of incidence (α₁) of the flow of the deposition material with reference to central axis 500 of the element 104-1. In some embodiments, as shown in FIG. 5A-1, owing to the height of element 104-1, height of element 104-2, and the width of trench 106-1, first side wall 208-1 of element 104-1 and trench surface 206-1 of trench 106-1 are completely shadowed (e.g., obscured to the flow of the deposition material, due to line of sight effect) by element 104-2 for the given predetermined angle of incidence α₁. In such embodiments, only the surfaces (e.g., top surface 204-1 of element 104-1, FIG. 5A-1) that are not shadowed by surrounding features (e.g., not shadowed by element 104-2, FIG. 5A-1) are deposited on with the deposition material (e.g., as shown in FIG. 5B-1).

Further, as shown in FIG. 5A-2, for a second predetermined angle of incidence α₂ (e.g., less than the first predetermined angle α₁), only portions of first side wall 208-1 of element 104-1 are shadowed (e.g., due to line of sight effect). However, the entire trench surface 206-1 is still shadowed by element 104-2. Along similar lines as described with reference to FIG. 5A-1 and FIG. 5B-1 above, only the surfaces (e.g., top surface 204-1 of element 104-1 and a portion of side wall 208-1, FIG. 5B-2) that are not shadowed by surrounding features (e.g., not shadowed by element 104-2) are deposited on with the deposition material (e.g., as shown in FIG. 5B-2).

Continuing along the example, as shown in FIG. 5A-3, for a third predetermined angle of incidence α₃ (e.g., less than the first predetermined angle α₁ and less than the second predetermined angle α₂), no portion of first side wall 208-1 of element 104-1 is shadowed (e.g., due to line of sight effect). As shown in FIG. 5A-3, only the entire trench surface 206-1 is shadowed by element 104-2. Along similar lines as described with reference to FIG. 5A-1 and FIG. 5B-1 above, only the surfaces (e.g., top surface 204-1 of element 104-1 and complete side wall 208-1, FIG. 5B-3) that are not shadowed by surrounding features (e.g., not shadowed by element 104-2) are deposited on with the deposition material (e.g., as shown in FIG. 5B-3).

In other words, for the same device geometry (e.g., substantially identical geometry shown in FIGS. 5A-1, 5A-2, and 5A-3), by varying the predetermined angle of incidence of the flow of the deposition material, the deposition profile obtained can be varied (e.g., as shown respectively in FIGS. 5B-1, 5B-2, and 5B-3) to obtain varying device topography in accordance with a value of the predetermined angle of incidence of the flow of the deposition material.

Conversely, FIG. 5C illustrates the effect of substrate geometry on the material deposition profile for a given fixed angle of incidence of the deposition material. Accordingly, as shown in FIG. 5C, for the same predetermined angle of incidence α₁ of the direction of flow of the deposition material, the deposition profile obtained on each element can be varied in accordance with a height of the respective element relative to the height of surrounding features (e.g., surrounding elements) and the relative spacing between adjacent elements.

For example, element 104-1 is partially shadowed or obscured by element 104-2 (e.g., due to line of sight effect) thereby resulting in deposition of material only on the top surface of element 104-1 (e.g., not on its side wall or on the trench surface of trench 106-1, which are obscured or shadowed by element 104-2). On the other hand, for the same predetermined angle of incidence α₁, element 104-2 is not shadowed by element 104-3 (due to the height of element 104-3 being lower than the height of element 104-2), thereby resulting in a greater area of exposed (e.g., unobscured) surface of element 104-2 where the deposition material can be deposited due to line of sight effect. It should be noted that surrounding element 104-4, although not adjacent to element 104-3, shadows a portion of the side wall of element 104-2, thereby shaping the deposition profile by line of sight shadowing effect.

On the other hand, due to the relative height difference between element 104-3 and element 104-4, all surfaces of element 104-3 are completely obscured to the flow of deposition material for the given angle of incidence α₁ of the deposition material. Consequently, there is no deposition of material on any surface of element 104-3 due to line of sight effect.

In other words, for a given predetermined angle of incidence of the deposition material, the precise material deposition profile on surfaces of a respective element can be varied (e.g., substantially) in accordance with a relative height of the respective element with respect to relative heights of neighboring (e.g., adjacent) elements and relative spacing between adjacent elements.

Further, FIG. 5D illustrates the effect of a change in the polarity or direction of flow of the deposition material (e.g., for the same or different deposition material) on the deposition profile. In some embodiments, as shown in FIGS. 5D-1 and 5D-2, after deposition of a first deposition material (e.g., material 550-1) on a respective element (e.g., element 104-1, including a first side wall) at a first predetermined angle of incidence α₄, a polarity of the predetermined angle of incidence with respect to the central axis of the respective element (e.g., central axis 500) can be varied (e.g., switched from right-to-left to left-to-right, with reference to the orientation of the device geometry shown in FIG. 5D) to deposit substantially the same deposition material or a different deposition material (e.g., material 550-2) on the respective element (e.g., element 104-1, including a second side wall) at a second predetermined angle of incidence α₅ with respect to the central axis of the respective element (e.g., central axis 500).

In other words, the deposition profile formed on one or more surfaces of a respective element by oblique angle deposition (e.g., using line of sight effect) can be varied in accordance with a value of the predetermined angle of incidence of the flow of deposition material, a polarity of the predetermined angle of incidence of the flow of deposition material, and/or the material of deposition (e.g., distinct graphene initiating materials which can result in or impact on distinct graphene growth profiles and/or different graphene layer encapsulation properties).

In some embodiments, the deposition profile formed on one or more surfaces of a respective element by oblique angle deposition (e.g., using line of sight effect) is determined by (i) a first amount of time a first material is deposited, (ii) a first predetermined angle of incidence of the flow of deposition material during the first amount of time, (iii) a first polarity of the first predetermined angle of incidence of the flow of deposition material during the first amount of time, (iv) a second amount of time a second material is deposited, (v) a second predetermined angle of incidence of the flow of deposition material during the second amount of time, and (vi) a second polarity of the second predetermined angle of incidence of the flow of deposition material during the second amount of time.

In some embodiments, the deposition profile formed on one or more surfaces of a respective element by oblique angle deposition (e.g., using line of sight effect) is determined by (i) a first amount of time a first material is deposited, (ii) a first predetermined angle of incidence of the flow of deposition material during the first amount of time, (iii) a first polarity of the first predetermined angle of incidence of the flow of deposition material during the first amount of time, (iv) a second amount of time a second material is deposited, (v) a second predetermined angle of incidence of the flow of deposition material during the second amount of time, (vi) a second polarity of the second predetermined angle of incidence of the flow of deposition material during the second amount of time, (vii) a third amount of time a third material is deposited, (viii) a third predetermined angle of incidence of the flow of deposition material during the third amount of time, and (ix) a third polarity of the third predetermined angle of incidence of the flow of deposition material during the third amount of time. In some embodiments the first and second material are the same. In some embodiments the first and second material are different. In some embodiments the first, second, and third materials are the same. In some embodiments one of the first, second, and third materials are different from the other of the first, second, and third materials. One of skill in the art will appreciate that devices in which a plurality of different predetermined angles of incidence of the flow of deposition material are used in a corresponding plurality of different time periods may be invoked using the methods disclosed herein to manufacture devices having any number of different profiles. This plurality of different predetermined angles of incidence may comprise 2, 3, 4, 5, 6, 7, 8, 9, 10, 11, 12, or more different predetermined angles of incidences. Moreover, the predetermined angle of incidence may be adjusted continuously between predetermined ranges in order to manufacture yet other devices.

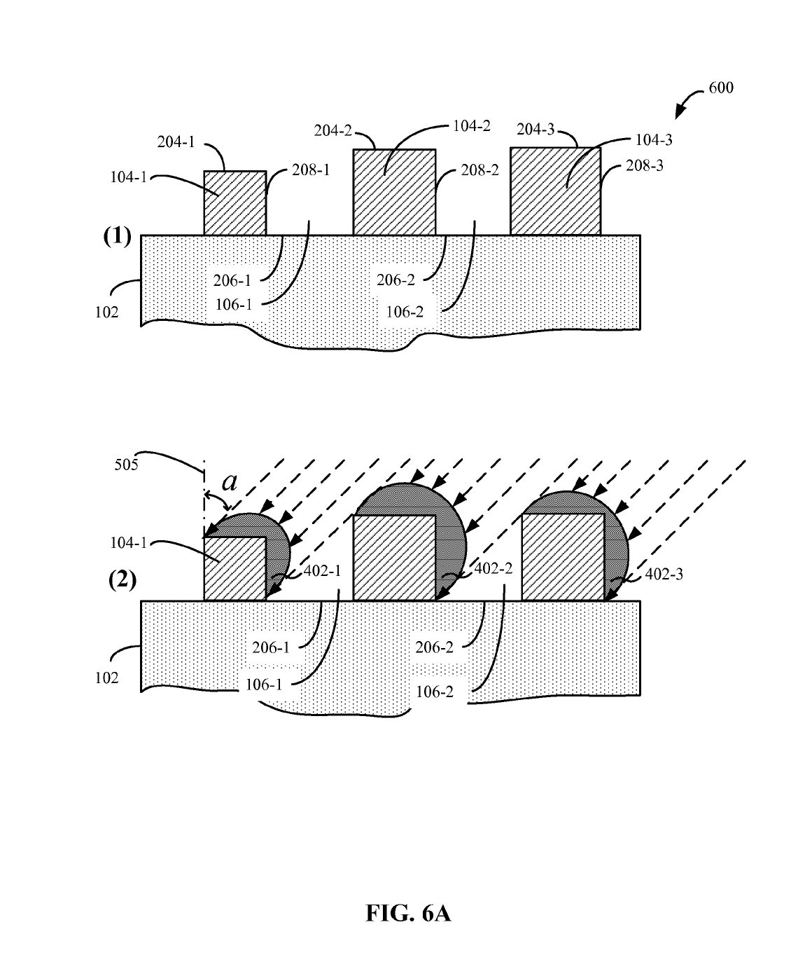

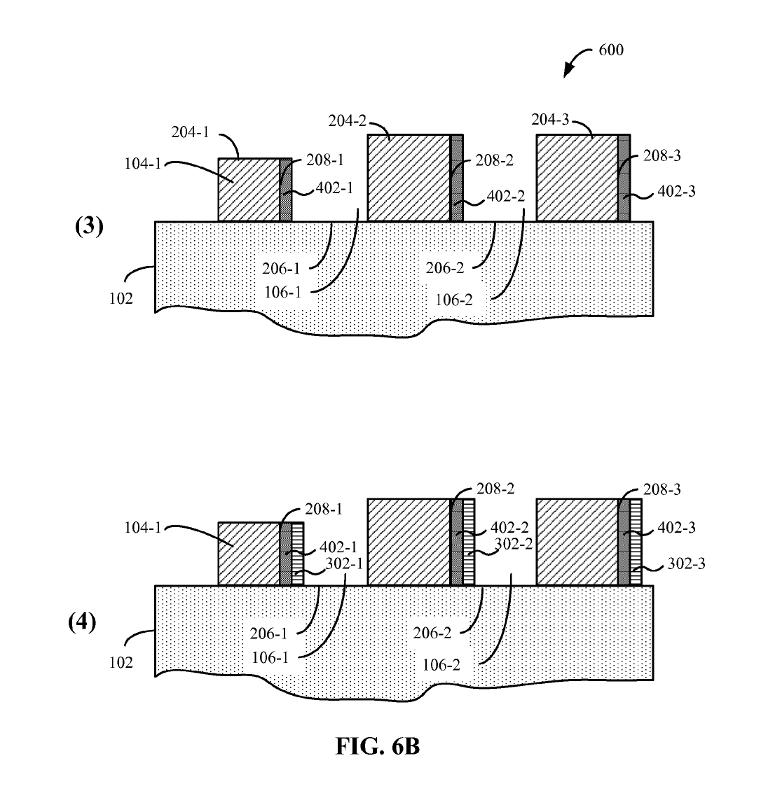

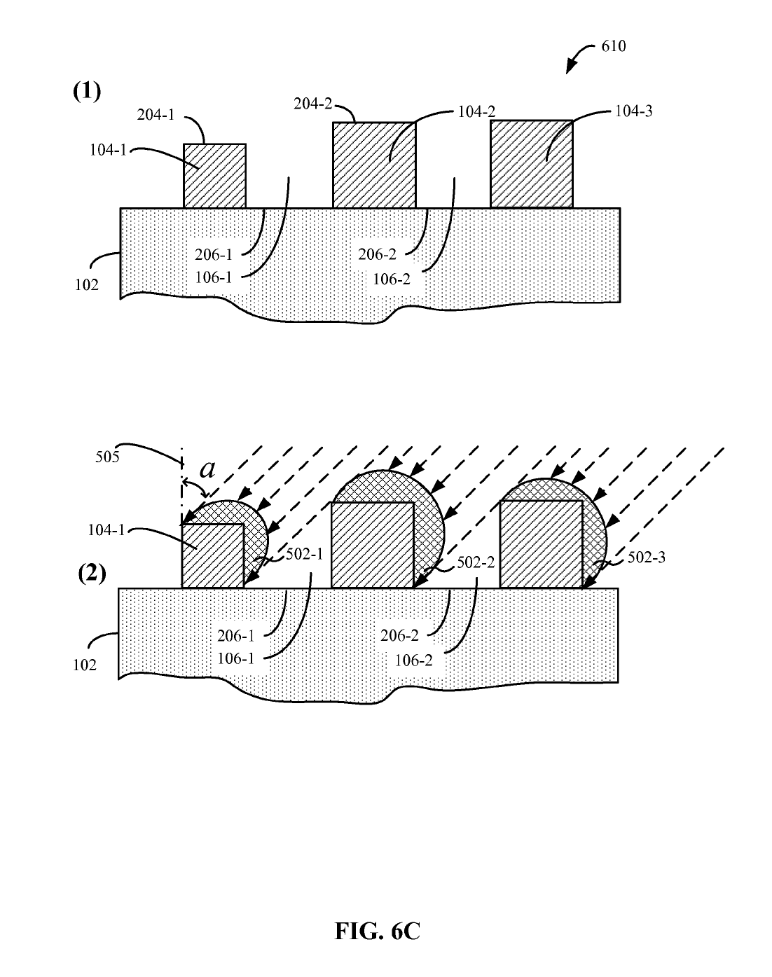

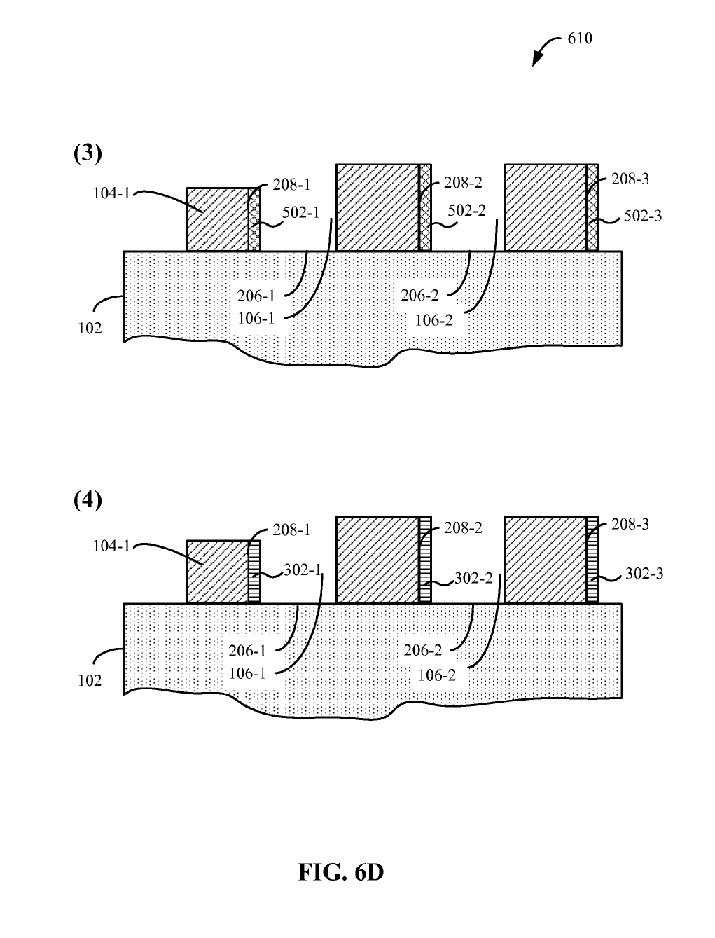

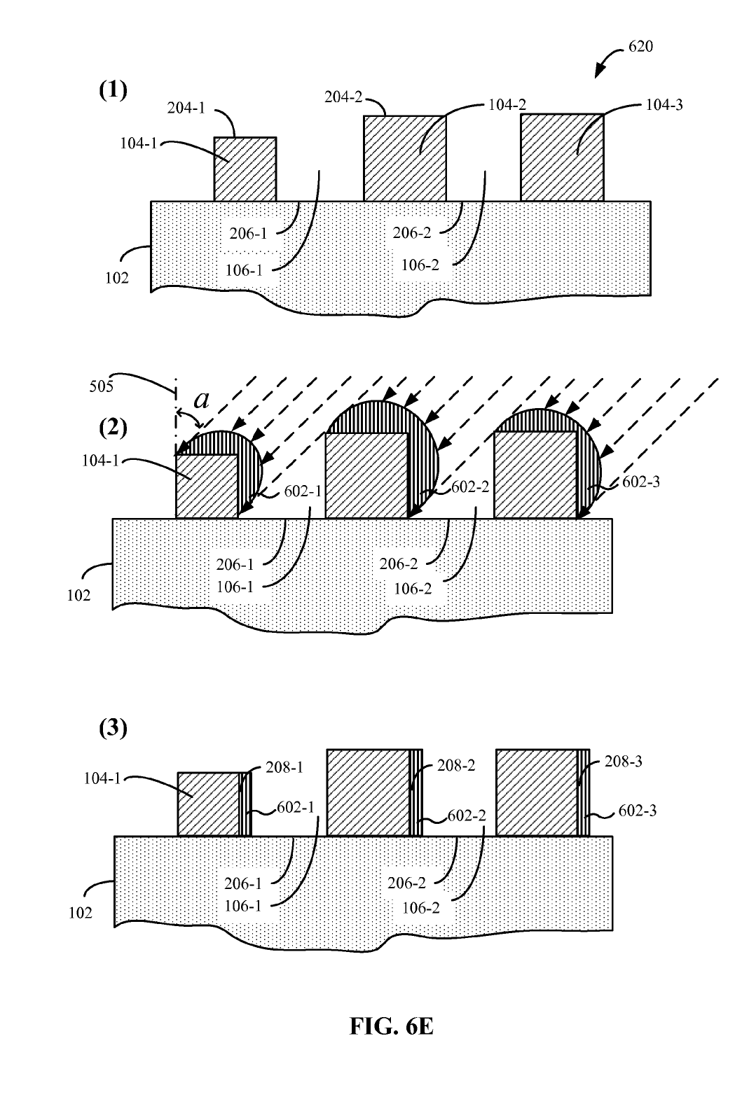

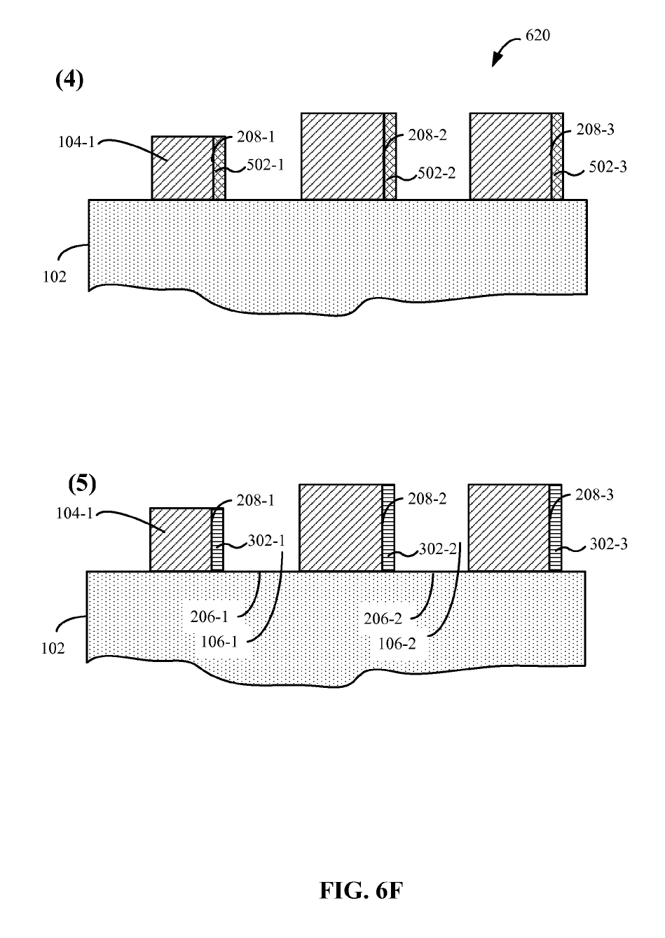

FIGS. 6A-6B include flow diagrams illustrating process 600 for fabricating graphene devices by exemplary methods (e.g., including oblique angle deposition of a metal based graphene initiating layer) in accordance with an embodiment of the present disclosure. It will be understood that, in some embodiments, the illustrative devices shown in FIGS. 6A-6F are cross-sectional views of the device topography. The graphene device topography formed by the exemplary methods described in FIGS. 6A-6F have a top view as illustrated in FIG. 2A (e.g., with graphene growth on a single corresponding side wall of each respective element of the plurality of elements 104, the single corresponding side wall of each respective element of the plurality of elements 104 lying in a plane parallel to corresponding side walls of remaining elements of the plurality of elements 104).

Shown in step 600-1 of FIG. 6A, is a patterned substrate (e.g., fabricated by one or more of the process steps 400-1 and 400-2 described with reference to FIG. 4A; and process steps 410-1 and 410-2 described with reference to FIG. 4C). As shown in step 600-2 of FIG. 6A, a graphene initiating layer (e.g., metal based graphene initiating layer 402, including metal based graphene initiating layer 402-1 on first side wall 208-1 of first element 104-1, metal based graphene initiating layer 402-2 on side wall 208-2 of second element 104-2 and the like) is deposited (e.g., using oblique angle deposition or line of sight deposition) onto all of the surfaces of the patterned substrate directly exposed, e.g., via line of sight effect (e.g., as explained with reference to FIGS. 5A-5D), to the direction of flow of the graphene initiating material.

In some embodiments, as explained with reference to FIGS. 5A-5C above, the specific surfaces of respective elements that are exposed to line of sight deposition are determined based on the relative heights of the respective elements in relation to the heights of adjacent elements, the relative separation between the respective elements and adjacent elements, and based on a predetermined angle of incidence α between the direction of flow of the graphene initiating material and the central axis of the elements on the patterned substrate.

In some embodiments, the metal graphene initiating layer is deposited through one or more of chemical vapor deposition (CVD), line of sight evaporation followed by line of sight deposition, line of sight sputtering of a target followed by line of sight sputter deposition, line of sight ion implantation of the graphene initiating material onto the first surface 204-1 and the first side wall 208-1-b of the first element 104-1 but not onto the second surface 206-1 of the first trench 106-1. In some embodiments, the graphene initiating layer substantially comprises a metal selected from the group consisting of: platinum, gold, palladium, ruthenium, aluminum, titanium, tungsten, cadmium, copper, nickel, nickel foam, iron, or any combination thereof.

As shown in step 600-3 of FIG. 6B, after depositing the graphene initiating layer (e.g., metal based graphene initiating layer 402), portions of the graphene initiating layer (e.g., the graphene initiating layer on the top surface of each element, such as graphene initiating layer on first surface 204-1 of element 104-1, graphene initiating layer on top surface 204-2 of element 104-2, and the like) are removed (e.g., directionally etched, anisotropically etched, or etched preferentially in one or more directions or axes of etching compared to at least another direction or axis) to retain graphene initiating layer on the side walls of the respective elements (e.g., on side wall 208-1 of element 104-1, side wall 208-2 of element 104-2, and the like).

As shown in step 600-4 of FIG. 6B, a graphite-based structure is formed by generating graphene using the graphene initiating layer (e.g., generating graphene layers 302-1, 302-2 and the like using segmented metal graphene initiating layers 402-1, 402-2 and the like, respectively). In some embodiments, graphene is generated using the graphene initiating layer 402 by growing a carbon material on the graphene initiating layer thereby forming the graphite-based structure. In some embodiments, the carbon material is deposited on the graphene initiating layer and the deposited carbon material is heated thereby forming the graphite-based structure.

FIGS. 6C-6D include flow diagrams illustrating process 610 for fabricating graphene device topography by exemplary methods (e.g., including oblique angle deposition of a silicon carbide based graphene initiating layer) in accordance with an embodiment of the present disclosure.

Shown in step 610-1 of FIG. 6C, is a patterned substrate (e.g., fabricated by one or more of the process steps 400-1 and 400-2 described with reference to FIG. 4A; and process steps 410-1 and 410-2 described with reference to FIG. 4C). As shown in step 610-2 of FIG. 6C, a graphene initiating layer (e.g., silicon carbide based graphene initiating layer 502, including silicon carbide based graphene initiating layer 502-1 on first side wall 208-1 of first element 104-1, silicon carbide based graphene initiating layer 502-2 on side wall 208-2 of second element 104-2 and the like) is deposited (e.g., using oblique angle deposition or line of sight deposition) onto all of the surfaces of the patterned substrate directly exposed, e.g., via line of sight effect (e.g., as explained with reference to FIGS. 5A-5D), to the direction of flow of the graphene initiating material.

As shown in step 610-3 of FIG. 6D, after depositing the graphene initiating layer (e.g., silicon carbide based graphene initiating layer 502), portions of the graphene initiating layer (e.g., the graphene initiating layer on the top surface of each element, such as graphene initiating layer on first surface 204-1 of element 104-1, graphene initiating layer on top surface 204-2 of element 104-2, and the like) are removed (e.g., directionally etched, anisotropically etched, or etched preferentially in one or more directions or axes of etching compared to at least another direction or axis) to retain graphene initiating layer on the side walls of the respective elements (e.g., on side wall 208-1 of element 104-1, side wall 208-2 of element 104-2, and the like).

As shown in step 610-4 of FIG. 6D, a graphite-based structure is formed by generating graphene using the graphene initiating layer (e.g., generating graphene layers 302-1 and 302-2 using segmented silicon carbide based graphene initiating layers 502-1 and 502-2, respectively). In some embodiments, when graphene initiating layer 502 is made of silicon carbide, graphene layers 302 are generated using graphene initiating layers 502 by heating the silicon carbide to vaporize elemental silicon in the silicon carbide, thereby forming graphite-based structure. More generally, in some embodiments, where the graphene initiating layer substantially comprises a compound of carbon (e.g., silicon carbide), graphene is generated by heating the graphene initiating layer to vaporize an element other than carbon from the compound of carbon, thereby forming the graphite-based structure.

FIGS. 6E-6F include flow diagrams illustrating process 620 for fabricating graphene device topography by exemplary methods (e.g., including oblique angle deposition of a silicon based graphene initiating layer) in accordance with an embodiment of the present disclosure.

Shown in step 620-1 of FIG. 6E, is a patterned substrate (e.g., fabricated by one or more of the process steps 400-1 and 400-2 described with reference to FIG. 4A; and process steps 410-1 and 410-2 described with reference to FIG. 4C). As shown in step 620-2 of FIG. 6E, a graphene initiating layer (e.g., silicon based graphene initiating layer 602, including silicon based graphene initiating layer 602-1 on first side wall 208-1 of first element 104-1, silicon based graphene initiating layer 602-2 on side wall 208-2 of second element 104-2 and the like) is deposited (e.g., using oblique angle deposition or line of sight deposition) onto all of the surfaces of the patterned substrate directly exposed, e.g., via line of sight (e.g., as explained with reference to FIGS. 5A-5D), to the direction of flow of the graphene initiating material.

As shown in step 620-3 of FIG. 6E, after depositing the graphene initiating layer (e.g., silicon based graphene initiating layer 602), portions of the graphene initiating layer (e.g., the graphene initiating layer on the top surface of each element, such as graphene initiating layer on first surface 204-1 of element 104-1, graphene initiating layer on top surface 204-2 of element 104-2, and the like) are removed (e.g., directionally etched, anisotropically etched, or etched preferentially in one or more directions or axes of etching compared to at least another direction or axis) to retain graphene initiating layer on the side walls of the respective elements (e.g., on side wall 208-1 of element 104-1, side wall 208-2 of element 104-2, and the like).

As shown further in step 620-4 and 620-5 of FIG. 6F, a graphite-based structure is formed by generating graphene using the graphene initiating layer 602 (e.g., including segmented silicon graphene initiating layers 602-1 on the side walls of first element 104-1 and silicon graphene initiating layers 602-2 on the side walls of second element 104-2). As shown in step 620-4, in some embodiments, graphene is generated using the graphene initiating layer by depositing elemental carbon on or into the silicon graphene initiating layer and by subsequently converting the silicon graphene initiating layer into silicon carbide (e.g., silicon carbide layer 502, including silicon carbide layers 502-1 on the side wall of first element 104-1 and silicon carbide layers 502-2 on the side wall of second element 104-2) by enabling a chemical reaction of the silicon graphene initiating layer with the deposited elemental carbon. In some embodiments, elemental carbon is deposited on or into the silicon graphene initiating layer 602 by doping the silicon graphene initiating layer 602 through implantation of the elemental carbon into the silicon graphene initiating layer 602. Further, as shown in step 420-5, the silicon carbide is heated to vaporize the silicon from the silicon carbide by reverse epitaxy, thereby forming the graphite-based structure (e.g., including segmented graphene layers 302-1 on the side wall of first element 104-1 and segmented graphene layers 302-2 on the side wall of second element 104-2).

It will be understood that, in some embodiments (e.g., described with reference to FIGS. 6A-6F), the polarity of the predetermined angle of incidence and/or the deposition material (e.g., the graphene initiating material) is varied (e.g., as illustrated in and described with reference to FIG. 5D). In such embodiments, graphene growth can be initiated (e.g., graphene can be grown) on two side walls of a respective element, where the two side walls lie in parallel planes. In such embodiments, the graphene device topography formed by these exemplary methods have a top view as illustrated in FIG. 2C (e.g., with graphene growth on a two corresponding side walls of each respective element of the plurality of elements 104, the two corresponding side walls of each respective element of the plurality of elements 104 lying in mutually parallel planes which are in turn parallel to planes formed by corresponding side walls of remaining elements of the plurality of elements 104).

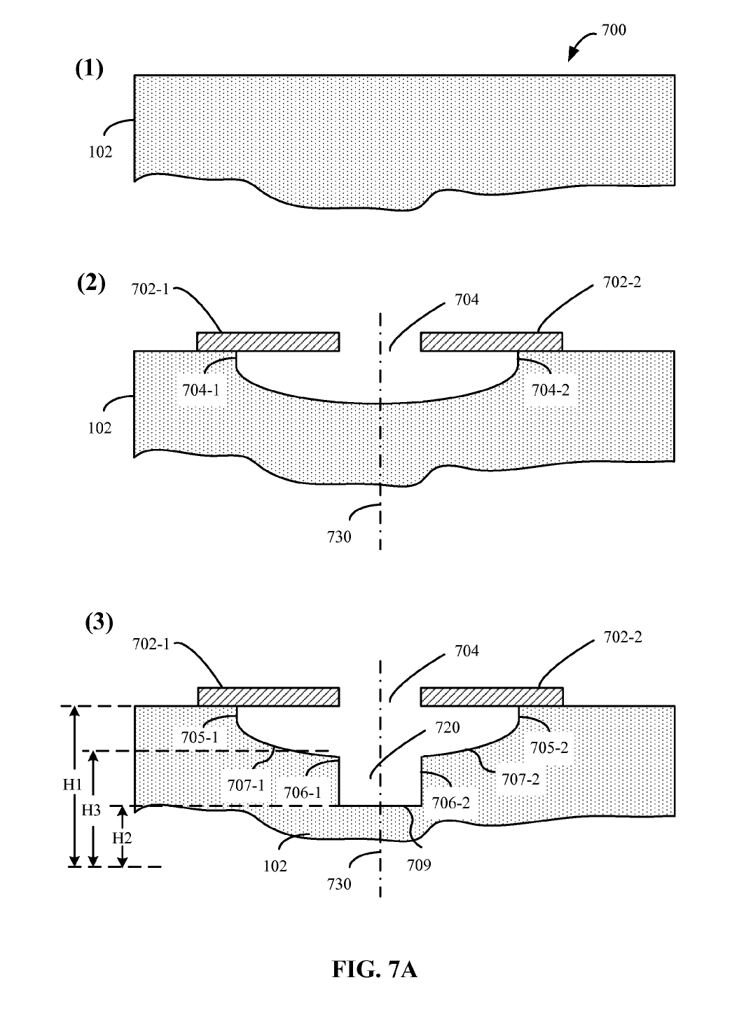

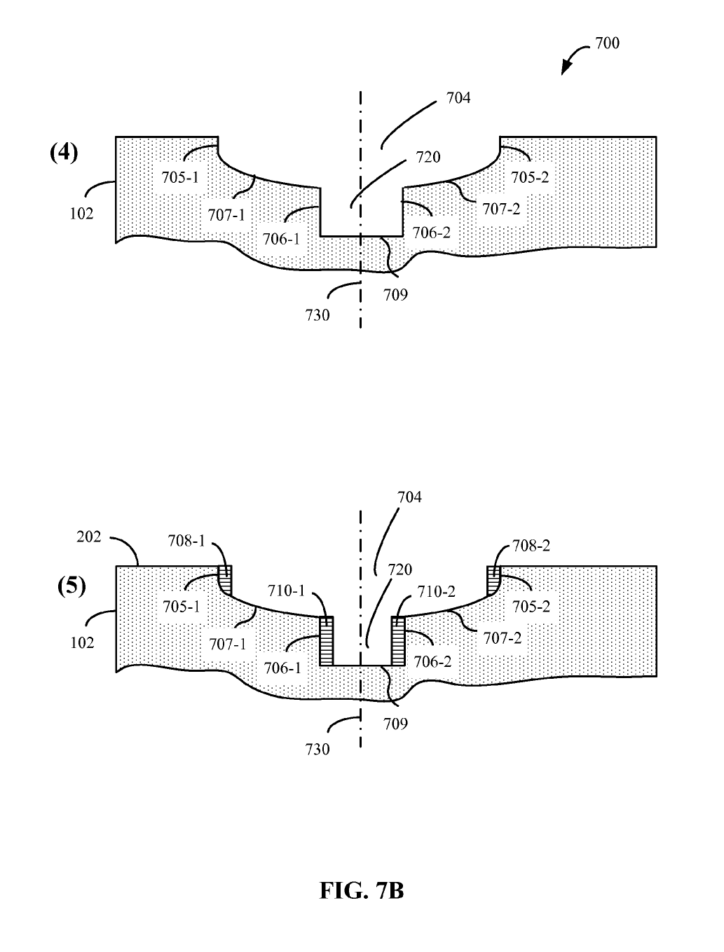

FIGS. 7A-7B include flow diagrams illustrating process 700 for fabricating graphene device topography (e.g., with device enhancements such as plasmonic structures) with segmented graphene films fabricated by exemplary methods in accordance with an embodiment of the present disclosure. In some embodiments, patterning the substrate to form a plurality of elements and a plurality of trenches comprises patterning (e.g., performing one or more etching steps) holes into a layer of the substrate. In such embodiments, the holes substantially include the trenches and the regions or portions of the substrate layer between adjacent holes (e.g., the portions of the substrate layer that are not etched), form the plurality of elements.

In some embodiments, the holes (e.g., including the trenches) are formed by two or more consecutive etch steps. Shown in step 700-1 of FIG. 7A, is a substrate comprising one or more substrate layers (e.g., including substrate layer 102). As shown in step 700-2 of FIG. 7A, a first respective portion of the substrate (e.g., substrate layer 102) is removed or consumed by isotropically etching the first wide trench portion 704 into the substrate (e.g., in a location of the substrate defined substantially by the opening between the photoresist layers 702-1 and 702-2). In some embodiments, isotropically etching the first wide trench portion 704 substantially comprises a non-directional etch and results in a uniform removal or etching of the substrate material in all directions resulting in a uniform, non-directional etch profile.

Further, as shown in step 700-3 of FIG. 7A, subsequent to consuming the first respective portion of the substrate, a second respective portion of the substrate (e.g., substrate layer 102) is consumed by anisotropically etching the second narrow trench portion 720 into the substrate contiguous with the first wide trench portion 704.

As shown in step 700-4 of FIG. 7B, the photoresist layers 702-1 and 702-2 are removed (e.g., by chemical or mechanical processes) to form the plasmonic structure shown in step 700-4. Further, as shown in step 700-5 of FIG. 7B, segmented graphene layers (e.g., segmented graphene layers 708-1 and 708-2 as well as 710-1 and 710-2) are formed on one or more of the side walls (e.g., on side walls 705-1 and 705-2; and side walls 706-1 and 706-2) of the plasmonic structure. In some embodiments, the step of generating segmented graphene or graphene layers on the side walls of the plasmonic structure includes generating one or more graphene initiating layers on the side walls (e.g., using one or more of steps described above with reference to processes 400, 410, 420; or 600, 610, 620) of the plasmonic structure. It should be understood that the plasmonic structure described (e.g., with reference to process 700 including a first wide trench portion 704 and a second narrow trench portion 720), is merely illustrative and representative; and the plasmonic structure can be configured to include shapes, relative or absolute dimensions of the trench portions, and numbers of trench portions not specifically listed here.

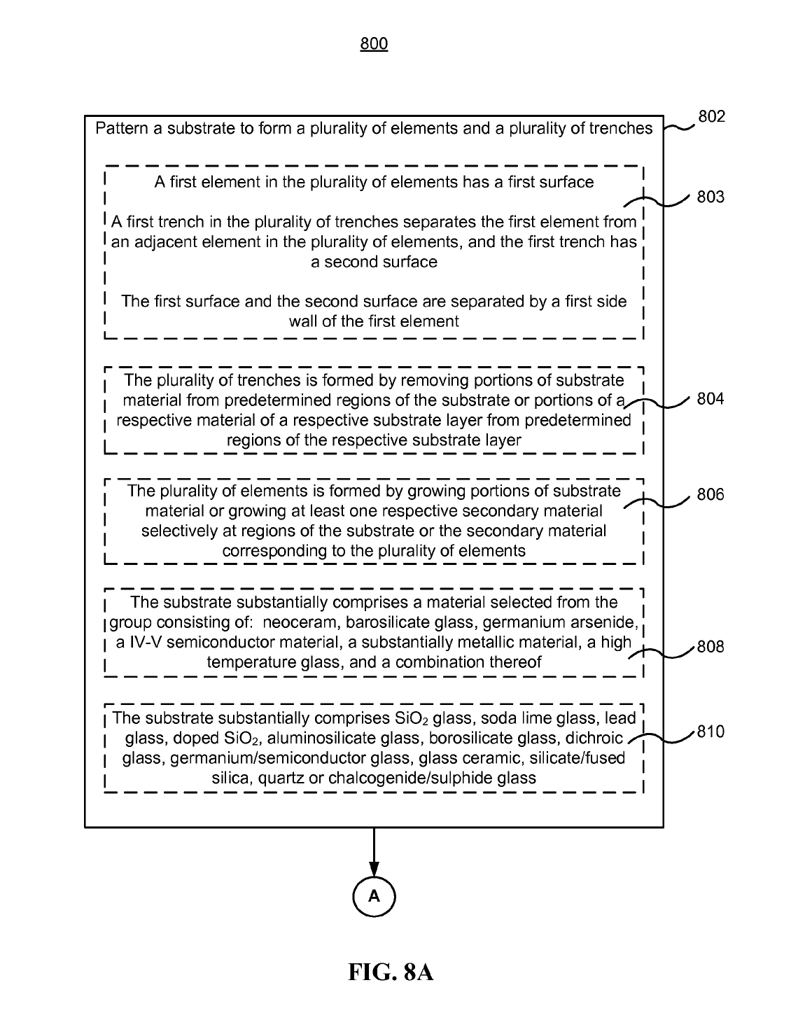

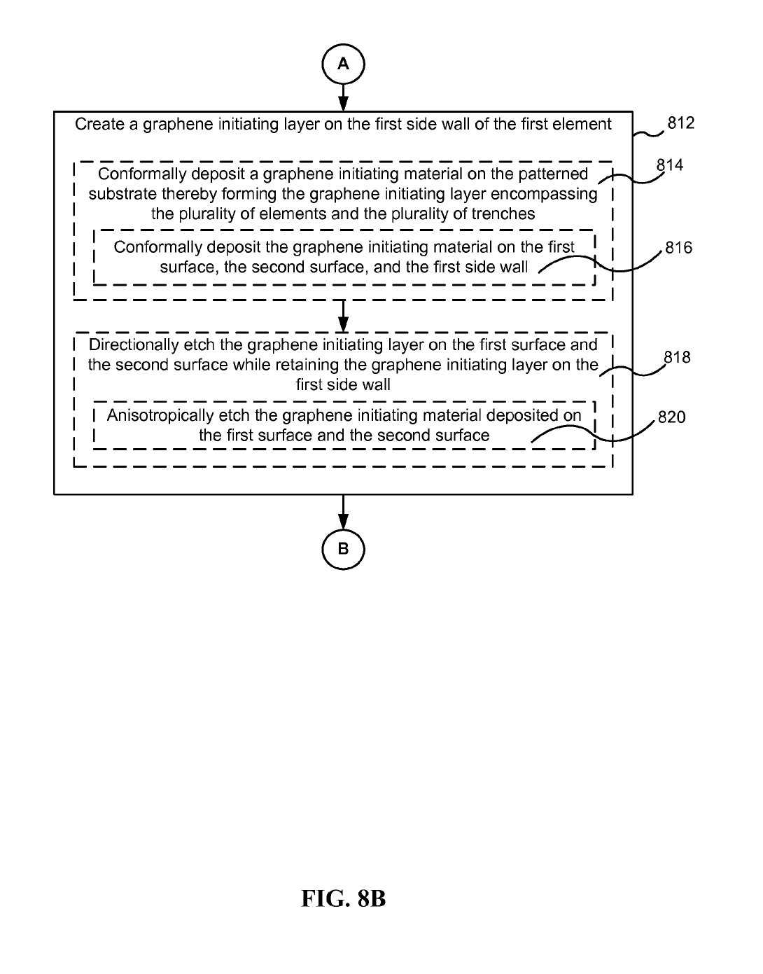

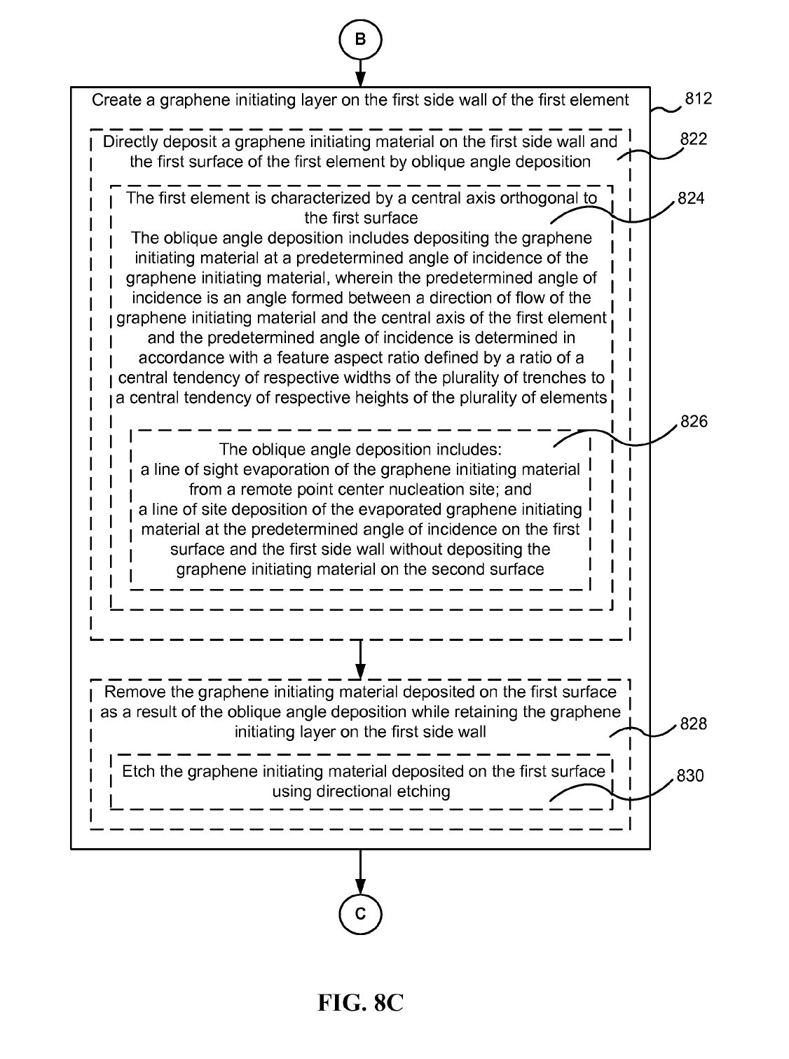

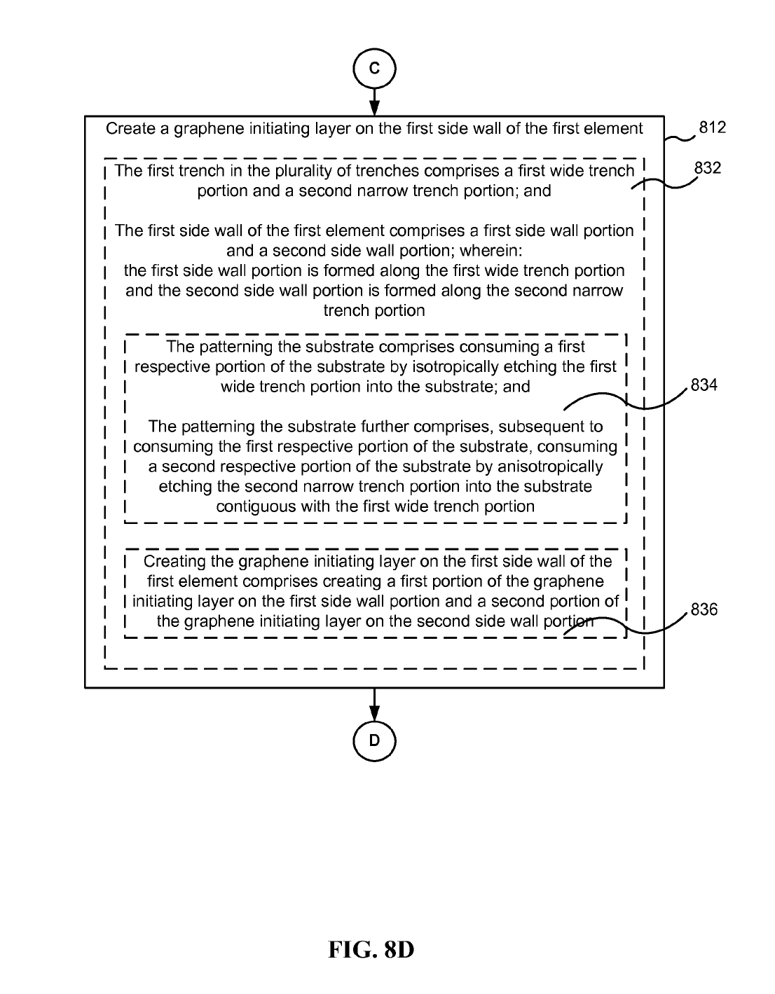

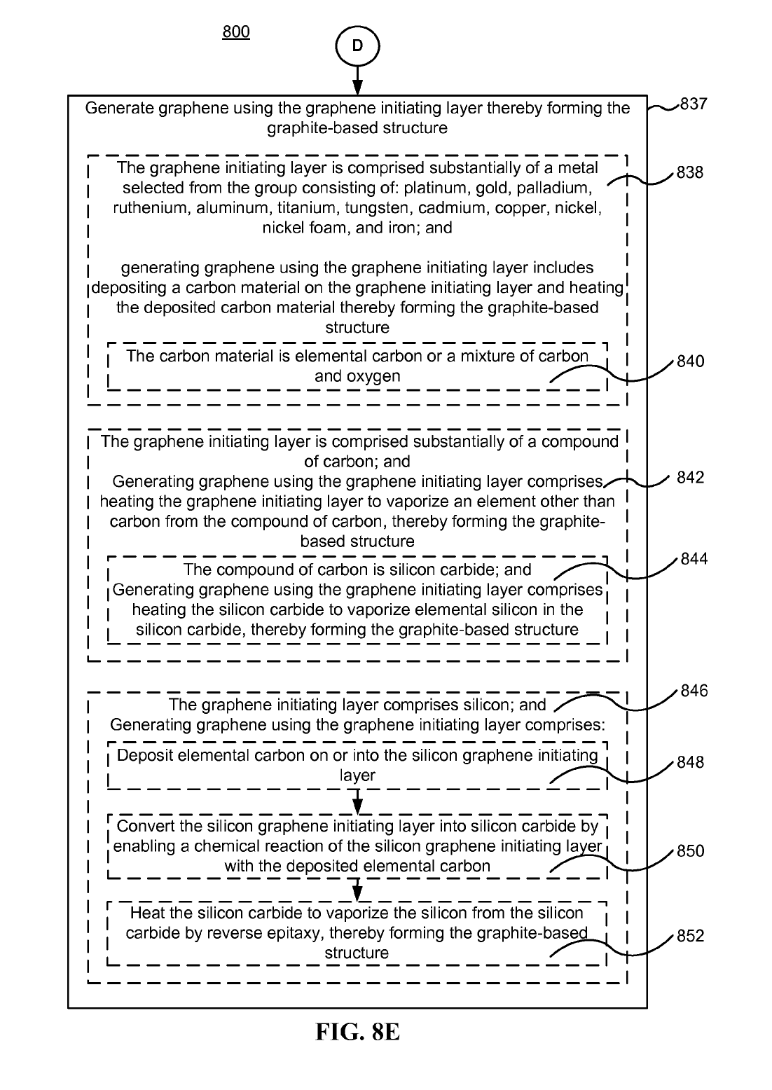

FIGS. 8A-8E include a flowchart illustrating method 800 for fabricating graphene device topography (e.g., method of forming a graphite-based structure on a substrate), according to certain embodiments of the invention.

The method includes patterning (802) a substrate thereby forming a plurality of elements (e.g., plurality of elements 104, including elements 104-1, 104-2 and the like as described with reference to FIGS. 1A-1B, 2A-2B, 2C-2D, and 3), each respective element in the plurality of elements separated from an adjacent element by a corresponding trench in a plurality of trenches (e.g., plurality of trenches 106, including trenches 106-1, 106-2 and the like as described with reference to FIGS. 1A-1B, 2A-2B, 2C-2D, and 3) on the substrate (e.g., substrate 102, FIGS. 1A-1B, 2A-2B, 2C-2D, and 3). A first element in the plurality of elements has (803) a first surface (e.g., first surface 204-1 of element 104-1 as described with reference to FIGS. 1B, 2B, and 2D). A first trench in the plurality of trenches separates the first element from an adjacent element in the plurality of elements, and the first trench has a second surface (e.g., second surface 206-1 of trench 106-1 as described with reference to FIGS. 1B, 2B, and 2D). The first surface and the second surface are separated by a first side wall of the first element (e.g., first side wall 208-1-8 of first element 104-1, as described with reference to FIGS. 1B, 2B, and 2D). The first surface is characterized by a first elevation (e.g., first elevation H1 of first surface 204-1 of first element 104-1, as shown in FIG. 1B). The second surface is characterized by a second elevation (e.g., second elevation H2 of second surface 206-1 of first trench 106-1, as shown in FIG. 1B). A first orthogonal projection of the first surface and a second orthogonal projection of the second surface onto a common plane are contiguous or overlapping. The first average elevation is other than the second average elevation (e.g., H1 and H2 are distinct, as shown in FIG. 1B).

In some embodiments, the plurality of trenches is formed (804) by removing portions of substrate material from predetermined regions of the substrate. In some embodiments, removing portions of the substrate material includes etching the plurality of trenches into the substrate (e.g., as explained with reference to steps 400-1 and 400-2, FIG. 4A). In some embodiments, the substrate includes a plurality of layers (e.g., respective substrate layer 103 and substrate layer 102, FIG. 4A). In some embodiments, the plurality of layers includes a first substrate layer and the substrate comprises a plurality of materials, including a first material of the first substrate layer; and the plurality of trenches are formed by removing portions of the first material from predetermined regions of the first substrate layer (e.g., removing portions of first substrate layer 103 from regions 106-1 and 106-2 as described in step 400-2, FIG. 4A). In some embodiments, removing portions of the first material from predetermined regions of the first substrate layer includes etching the plurality of trenches into the first substrate layer (e.g., as described in step 400-2, FIG. 4A). In some embodiments, the first substrate layer comprises a photoresist material, and removing portions of the first material from predetermined regions of the first substrate layer includes removing a portion of the photoresist material using photolithography. In some embodiments, etching the plurality of trenches into the substrate includes photolithography, x-ray lithography, reactive ion-etching, plasma etching, sputter etching, e-beam direct writing, or a combination thereof.

In some embodiments, the plurality of elements is formed by growing (806) portions of substrate material selectively at regions of the substrate corresponding to the plurality of elements (e.g., as explained with reference to steps 410-1 and 410-2, portions of substrate material are grown to form elements 104-1 and 104-2). In some embodiments, the substrate comprises a first material; the plurality of elements is formed by growing at least one respective secondary material, distinct from the first material, selectively on regions of the substrate corresponding to the plurality of elements.

In some embodiments, the respective secondary material is composed of one or more of: a dielectric material, a metal oxide, a metal nitride, a semi-conductor material, a metal, or a combination thereof. In some embodiments, the respective secondary material comprises silicon dioxide, silicon nitride, or a combination thereof. In some embodiments, the respective secondary material comprises silicon dioxide, silicon nitride, or a combination thereof. In some embodiments, the respective secondary material comprises titanium dioxide. In some embodiments, the respective secondary material comprises titanium nitride. In some embodiments, the respective secondary material comprises silicon, gallium arsenide, germanium, or a combination thereof. In some embodiments, the respective secondary material comprises a group VII-IX metal including one or more of metals selected from the group consisting of copper, nickel, iron, platinum, gold, palladium, and ruthenium. In some embodiments, the respective secondary material comprises aluminum, titanium, tungsten, cadmium, silver, platinum, tantalum, hafnium, vanadium, or a combination thereof. In some embodiments, the respective secondary material is titanium, titanium dioxide, titanium nitride, or any combination thereof. In some embodiments, the respective secondary material is tantalum, tantalum oxide, tantalum nitride, or any combination thereof. In some embodiments, the respective secondary material is hafnium, hafnium oxide, hafnium nitride, or any combination thereof. In some embodiments, the respective secondary material is vanadium, vanadium dioxide, vanadium nitride, or any combination thereof.

In some embodiments, the substrate is comprised (808) substantially of a material selected from the group consisting of: neoceram, barosilicate glass, germanium arsenide, a IV-V semiconductor material, a substantially metallic material, a high temperature glass, or a combination thereof. In some embodiments, the substrate substantially comprises (810) SiO₂ glass, soda lime glass, lead glass, doped SiO₂, aluminosilicate glass, borosilicate glass, dichroic glass, germanium/semiconductor glass, glass ceramic, silicate/fused silica, quartz or chalcogenide/sulphide glass.

Referring to FIG. 8B, the method further comprises creating (812) a graphene initiating layer on the first side wall of the first element (e.g., on first side wall 208-1-b of first element 104-1 as shown in FIGS. 1A-1B, 2A-2D, and 4A-4F; or on first side wall 208-1 of first element 104-1 as shown in FIGS. 6A-6F), as described further with reference to steps 814-836. In some embodiments, the graphene initiating layer comprises one or more of: a dielectric material, a metal oxide, a metal nitride, a semi-conductor material, a metal, or a combination thereof.

In some embodiments, creating a graphene initiating layer on the first side wall of the first element comprises: conformally depositing (814) a graphene initiating material on the patterned substrate thereby forming the graphene initiating layer encompassing the plurality of elements and the plurality of trenches (e.g., conformally depositing graphene initiating material on the patterned substrate 102 thereby forming: conformal metal based graphene initiating layer 402 as explained with reference to step 400-3, FIG. 4A; or conformal silicon carbide based graphene initiating layer 502 as explained with reference to step 410-3, FIG. 4C; or conformal silicon based graphene initiating layer 602 as explained with reference to step 420-3, FIG. 4E). In some embodiments, conformally depositing the graphene initiating material on the patterned substrate includes conformally depositing (816) the graphene initiating material on the first surface, the second surface, and the first side wall (e.g., first surface 204-1, second surface 206-1, and first side wall 208-1-b, FIGS. 4A-4B).

In some embodiments, conformally depositing the graphene initiating material includes conformally depositing, through atomic layer deposition, the graphene initiating material onto the first surface, the second surface, and the first side wall. In some embodiments, conformally depositing the graphene initiating material includes conformally depositing through chemical vapor deposition, the graphene initiating material onto the first surface, the second surface, and the first side wall.

Further, in some embodiments, after conformally depositing a graphene initiating material on the patterned substrate, the method further includes directionally etching (818) the graphene initiating layer on the first surface and the second surface while retaining the graphene initiating layer on the first side wall (e.g., directionally etching metal based graphene initiating layer on first surface 204-1 and second surface 206-1 while retaining the metal based graphene initiating layer on first side wall 208-1-b, as explained with reference to step 400-4, FIG. 4B; directionally etching silicon carbide based graphene initiating layer on the first surface 204-1 and the second surface 206-1 while retaining the silicon carbide based graphene initiating layer on the first side wall 208-1-b, as explained with reference to step 410-4, FIG. 4D; or directionally etching silicon based graphene initiating layer on the first surface 204-1 and the second surface 206-1 while retaining the silicon based graphene initiating layer on the first side wall 208-1-b, as explained with reference to step 420-4, FIG. 4F). In some embodiments, directionally etching the graphene initiating layer includes anisotropically etching (820) the graphene initiating material deposited on the first surface and the second surface. In some embodiments, anisotropically etching the graphene initiating material deposited on the first surface and the second surface includes entirely consuming the graphene initiating material deposited on the first surface and the second surface using dry plasma etching.

In some embodiments, creating a graphene initiating layer on the first side wall of the first element comprises directly depositing (822) a graphene initiating material on the first side wall and the first surface of the first element by oblique angle deposition (e.g., depositing a metal based graphene initiating material on first side wall 208-1 and first surface 204-1 of first element 104-1 by oblique angle deposition as explained with reference to steps 600-1 and 600-2, FIG. 6A; depositing a silicon carbide based graphene initiating material on first side wall 208-1 and first surface 204-1 of first element 104-1 by oblique angle deposition as explained with reference to steps 610-1 and 610-2, FIG. 6C; or depositing a silicon based graphene initiating material on first side wall 208-1 and first surface 204-1 of first element 104-1 by oblique angle deposition as explained with reference to steps 620-1 and 620-2, FIG. 6E). In some embodiments, the first element is characterized (824) by a central axis (e.g., axis 505, FIGS. 5A-5E and FIGS. 6A, 6C, 6E) orthogonal to the first surface; and the oblique angle deposition includes depositing the graphene initiating material at a predetermined angle of incidence (e.g., angle α, FIG. 6A, 6C, 6E) of the graphene initiating material, where the predetermined angle of incidence is an angle formed between a direction of flow of the graphene initiating material and the central axis of the first element and the predetermined angle of incidence is determined in accordance with a feature aspect ratio defined by a ratio of respective widths of the plurality of trenches to respective heights of the plurality of elements (e.g., as explained with reference to FIGS. 5A-5C).

In some embodiments, the oblique angle deposition includes a line of sight chemical vapor deposition of the graphene initiating material at the predetermined angle of incidence so as to deposit the graphene initiating material on the first surface and the first side wall without depositing the graphene initiating material on the second surface. In some embodiments, the chemical vapor deposition includes plasma enhanced deposition. The oblique angle deposition includes (826): a line of sight evaporation of the graphene initiating material from a remote point center nucleation site; and a line of site deposition of the evaporated graphene initiating material at the predetermined angle of incidence on the first surface and the first side wall without depositing the graphene initiating material on the second surface. In some embodiments, the oblique angle deposition includes: a line of sight sputtering of a target substantially comprising the graphene initiating material, thereby resulting in a remote point center nucleation site; and a line of sight sputter-deposition of the graphene initiating material at the predetermined angle of incidence on the first surface and the first side wall without depositing the graphene initiating material on the second surface. In some embodiments, the oblique angle deposition includes a line of sight ion implantation of the graphene initiating material at the predetermined angle of incidence so as to implant the graphene initiating material on the first surface and the first side wall without implanting the graphene initiating material on the second surface.

In some embodiments, after directly depositing a graphene initiating material on the first side wall and the first surface of the first element, the creating a graphene initiating layer on the first side wall of the first element further comprises removing (828) the graphene initiating material deposited on the first surface as a result of the oblique angle deposition while retaining the graphene initiating layer on the first side wall (e.g., the metal based graphene initiating material deposited on first surface 204-1 as a result of the oblique angle deposition is removed while the metal based graphene initiating layer on the first side wall 208-1 is retained, as explained with reference to step 600-3, FIG. 6B; the silicon carbide based graphene initiating material deposited on first surface 204-1 as a result of the oblique angle deposition is removed while the silicon carbide based graphene initiating layer on the first side wall 208-1 is retained as explained with reference to step 610-3, FIG. 6D; or the silicon based graphene initiating material deposited on first surface 204-1 as a result of the oblique angle deposition is removed while the silicon based graphene initiating layer on the first side wall 208-1 is retained as explained with reference to step 620-3, FIG. 6F). In some embodiments, removing the graphene initiating material deposited on the first surface as a result of the oblique angle deposition includes etching (830) the graphene initiating material deposited on the first surface using directional etching.

In some embodiments, the method of creating a graphene initiating layer further includes coating the first surface of the first element with a top layer of photoresist, prior to directly depositing the graphene initiating material on the first side wall and the first surface of the first element by oblique angle deposition. In such embodiments, the directly depositing the graphene initiating material on the first side wall and the first surface of the first element by oblique angle deposition includes depositing the graphene initiating material on the top layer of photoresist formed on the first surface of the first element; and removing the graphene initiating material deposited on the first surface as a result of the oblique angle deposition includes a chemical lift-off of the graphene initiating material deposited on the first surface along with the top layer of photoresist formed on the first surface.

In some embodiments, the first trench in the plurality of trenches comprises (832) a first wide trench portion and a second narrow trench portion (e.g., first wide trench portion 704 and second narrow trench portion 720, FIGS. 7A-7B). The first wide trench portion and the second narrow trench portion are characterized by a common central axis (e.g., central axis 730, FIGS. 7A-7B) orthogonal to the second surface. An aperture of the first wide trench portion is proximal to the first surface of the first element and an aperture of the second narrow trench portion is proximal to and bounded by the second surface of the first trench. The first wide trench portion and the second narrow trench portion are contiguous and are punctuated at least partially by a first lateral intermediate trench surface and a second lateral intermediate trench surface (e.g., first lateral intermediate trench surface 707-1 and second lateral intermediate trench surface 707-2, FIGS. 7A-7B), the first lateral intermediate trench surface and the second lateral intermediate trench surface are substantially coplanar and lie in a first plane substantially parallel to each of a second plane comprising the first surface of the first element and a third plane comprising the second surface of the trench (e.g., trench surface 709, FIGS. 7A-7B). The first lateral intermediate trench surface and the second lateral intermediate trench surface are characterized by a third elevation (e.g., third elevation H3, FIG. 7A). The third elevation is other than the first elevation (e.g., first elevation H1, FIG. 7A) and the second elevation (e.g., second elevation H2, FIG. 7A) and has a value between respective values of the first elevation and the second elevation. In some embodiments, a first orthogonal projection of the first surface, the second orthogonal projection of the second surface, a third orthogonal projection of the first lateral intermediate trench surface and a fourth orthogonal projection of the second lateral intermediate trench surface onto a common plane are contiguous or overlapping.

In such embodiments, the first side wall of the first element comprises a first side wall portion and a second side wall portion (e.g., first side wall portion 705-1 and second side wall portion 705-1, FIGS. 7A-7B). The first side wall portion is formed along the first wide trench portion (e.g., first side wall portion 705-1 along first wide trench portion 704, FIG. 7A) and the second side wall portion is formed along the second narrow trench portion (e.g., second side wall portion 706-1 along second narrow trench portion 720, FIG. 7A). The first side wall portion and the second side wall portion are separated by the first lateral intermediate trench surface (e.g., first lateral intermediate trench surface 707-1, FIG. 7A). The first lateral intermediate trench surface and the second trench surface (e.g., second trench surface 709, FIG. 7A) are separated by the second side wall portion. The first side wall portion lies in a fourth plane and the second side wall portion lies in a fifth plane, wherein the fourth plane and the fifth plane are each substantially orthogonal to each of the first plane, the second plane, and the third plane.

In some embodiments, the patterning the substrate comprises consuming (834) a first portion of the substrate by isotropically etching the first wide trench portion into the substrate (e.g., as explained with reference to step 700-2, FIG. 7A). The patterning the substrate further comprises, subsequent to consuming the first portion of the substrate, consuming a second portion of the substrate by anisotropically etching the second narrow trench portion into the substrate contiguous with the first wide trench portion (e.g., as explained with reference to step 700-3, FIG. 7A). In such embodiments, the creating the graphene initiating layer on the first side wall of the first element comprises (836) creating a first portion of the graphene initiating layer on the first side wall portion and a second portion of the graphene initiating layer on the second side wall portion (e.g., creating first portion of the graphene initiating layer on the first side wall portion 705-1 and a second portion of the graphene initiating layer on the second side wall portion 706-1, FIGS. 7A-7B). In some embodiments, the creating the graphene initiating layer on the first side wall of the first element comprises: conformally depositing a graphene initiating material on the patterned substrate thereby forming the graphene initiating layer encompassing the plurality of elements and the plurality of trenches, including forming the graphene initiating layer on each of the first surface of the first element, the first side wall portion, the first lateral intermediate trench portion, the second lateral intermediate trench portion, and the second surface of the trench; and directionally etching the graphene initiating layer on the first surface of the first element, the second surface of the trench, the first lateral intermediate trench portion, and the second lateral intermediate trench portion, while retaining the graphene initiating layer on the first side wall thereby creating the first portion of the graphene initiating layer on the first side wall portion and the second portion of the graphene initiating layer on the second side wall portion (e.g., conformal deposition and anisotropic etch of graphene initiating material are explained with reference to processes 400, 410, and 420; FIGS. 4A-4F).

The method also comprises generating (837) graphene using the graphene initiating layer thereby forming the graphite-based structure, as described further with reference to steps 838-852.

In some embodiments, the graphene initiating layer is comprised (838) substantially of a metal selected from the group consisting of: platinum, gold, palladium, ruthenium, aluminum, titanium, tungsten, cadmium, copper, nickel, nickel foam, iron, or any combination thereof; and generating graphene using the graphene initiating layer includes depositing a carbon material on the graphene initiating layer and heating the deposited carbon material thereby forming the graphite-based structure (e.g., as explained with reference to process 400, FIGS. 4A-4B; and process 600, FIGS. 6A-6B). In some embodiments, the carbon material is (840) elemental carbon or a mixture of elemental carbon and oxygen.

In some embodiments, the graphene initiating layer is comprised (842) substantially of a compound of carbon; and generating graphene using the graphene initiating layer comprises heating the graphene initiating layer to vaporize an element other than carbon from the compound of carbon, thereby forming the graphite-based structure. In some embodiments, the compound of carbon is (844) silicon carbide; and generating graphene using the graphene initiating layer comprises heating the silicon carbide to vaporize elemental silicon in the silicon carbide, thereby forming the graphite-based structure (e.g., as explained with reference to process 410, FIGS. 4C-4D; and process 610, FIGS. 6C-6D).

In some embodiments, the graphene initiating layer comprises (846) silicon. In such embodiments, generating graphene using the graphene initiating layer comprises: depositing (848) elemental carbon on or into the silicon graphene initiating layer; converting (850) the silicon graphene initiating layer into silicon carbide by enabling a chemical reaction of the silicon graphene initiating layer with the deposited elemental carbon; and heating (852) the silicon carbide to vaporize the silicon from the silicon carbide by reverse epitaxy, thereby forming the graphite-based structure. In some embodiments, depositing elemental carbon on or into the silicon graphene initiating layer includes doping the silicon graphene initiating layer by implantation of the elemental carbon into the silicon graphene initiating layer (e.g., as explained with reference to process 420, FIGS. 4E-4F; and process 620, and FIGS. 6E-6F).

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

1. A method for forming a graphite-based structure comprising:
(A) patterning a substrate thereby forming a plurality of elements, each respective element in the plurality of elements separated from an adjacent element by a corresponding trench in a plurality of trenches on the substrate, wherein
(i) a first element in the plurality of elements has a first surface,
(ii) a first trench in the plurality of trenches separates the first element from an adjacent element in the plurality of elements, the first trench having a second surface,
(iii) the first surface and the second surface are separated by a first side wall of the first element,
(iv) the first surface is characterized by a first elevation,
(v) the second surface is characterized by a second elevation,
(vi) a first orthogonal projection of the first surface and a second orthogonal projection of the second surface onto a common plane are contiguous or overlapping, and
(vii) the first elevation is other than the average elevation;
(B) creating a graphene initiating layer on the first side wall of the first element; and
(C) generating graphene on the first side wall using the graphene initiating layer thereby forming the graphite-based structure.

2. The method of claim 1, wherein the plurality of trenches is formed by removing portions of substrate material from predetermined regions of the substrate.

3. The method of claim 2, wherein removing portions of the substrate material includes etching the plurality of trenches into the substrate.

4. The method of claim 1, wherein:
the substrate includes a plurality of layers, wherein the plurality of layers includes a first substrate layer and wherein the substrate comprises a plurality of materials, including a first material of the first substrate layer; and
the plurality of trenches are formed by removing portions of the first material from predetermined regions of the first substrate layer.

5. The method of claim 4, wherein removing portions of the first material from predetermined regions of the first substrate layer includes etching the plurality of trenches into the first substrate layer.

6. The method of claim 4, wherein:
the first substrate layer comprises a photoresist material; and
removing portions of the first material from predetermined regions of the first substrate layer includes removing a portion of the photoresist material using photolithography.

7. The method of claim 3, wherein etching the plurality of trenches into the substrate includes photolithography, X-ray lithography, reactive ion-etching, plasma etching, sputter etching, e-beam direct writing, or a combination thereof.

8. The method of claim 1, wherein the plurality of elements is formed by growing portions of substrate material selectively at regions of the substrate corresponding to the plurality of elements.

9. The method of claim 1, wherein the substrate comprises a first material and wherein the plurality of elements is formed by growing at least one secondary material, distinct from the first material, selectively on regions of the substrate corresponding to the plurality of elements.

10. The method of claim 9, wherein the secondary material comprises one or more of: a dielectric material, a metal oxide, a metal nitride, a semi-conductor material, a metal, or a combination thereof.

11. The method of claim 9, wherein the secondary material comprises silicon dioxide, silicon nitride, or a combination thereof.

12. The method of claim 9, wherein the secondary material comprises titanium dioxide.

13. The method of claim 9, wherein the secondary material comprises titanium nitride.

14. The method of claim 9, wherein the secondary material comprises silicon, gallium arsenide, germanium, or a combination thereof.

15. The method of claim 9, wherein the secondary material comprises a copper, nickel, iron, platinum, gold, palladium, ruthenium, or a combination thereof.

16. The method of claim 9, wherein the secondary material comprises aluminum, titanium, tungsten, cadmium, silver, platinum, tantalum, hafnium, vanadium, or a combination thereof.

17. The method of claim 9, wherein the secondary material comprises titanium, titanium dioxide, titanium nitride, or a combination thereof.

18. The method of claim 9, wherein the secondary material comprises tantalum, tantalum oxide, tantalum nitride, or a combination thereof.

19. The method of claim 9, wherein the secondary material comprises hafnium, hafnium oxide, hafnium nitride, or any combination thereof.

20. The method of claim 9, wherein the respective secondary material comprises vanadium, vanadium oxide, vanadium nitride, or any combination thereof.

21-76. (canceled)
